(19) United States
(12) Patent Application Publication
(10) Pub. No.: US 2023/0307015 A1
(43) Pub. Date: Sep. 28, 2023

(54) SEMICONDUCTOR DEVICE

(71) Applicant: KIOXIA CORPORATION, Tokyo (JP)

(72) Inventor: Mitsunori MATSUBA, Kawasaki Kanagawa (JP)

(21) Appl. No.: 17/898,363

(22) Filed: Aug. 29, 2022

(30) Foreign Application Priority Data
Mar. 23, 2022 (JP) 2022-046631

(51) Int. Cl. G11C 7/10; G11C 16/26; G11C 16/34

(52) U.S. Cl. CPC G11C 7/1006; G11C 16/26; G11C 16/34

(57) ABSTRACT

A semiconductor device includes a semiconductor circuit and a storage circuit. The semiconductor circuit consumes a first operating current when operating under a first operating condition and a second operating current when operating under a second operating condition. The second operating current is different from the first operating current. The storage circuit stores a correspondence between the first and second operating currents and the first and second operating conditions, respectively.

### CROSS-REFERENCE TO RELATED APPLICATION

This application is based upon and claims the benefit of priority from Japanese Patent Application No. 2022-046631, filed Mar. 23, 2022, the entire contents of which are incorporated herein by reference.

### FIELD

Embodiments described herein relate generally to a semiconductor device.

### BACKGROUND

A semiconductor device and an information processing system including a plurality of semiconductor devices are known.

### BRIEF DESCRIPTION OF THE DRAWINGS

FIG. 1 is a block diagram illustrating a configuration of an information processing system including a semiconductor device according to a first embodiment.

FIG. 2 is a diagram illustrating a configuration of a semiconductor package included in the semiconductor device according to the first embodiment.

FIG. 3 is a table illustrating an example of measurement conditions and operating currents stored in a storage circuit of a semiconductor chip in the first embodiment.

FIG. 4 is a flowchart illustrating a flow of processes for storing the measurement conditions and the operating currents in the semiconductor chip.

FIG. 5 is a diagram illustrating the measurement conditions and the operating currents stored in storage circuits of semiconductor chips.

FIG. 6 is a flowchart illustrating an operation of controlling a current supplied to the semiconductor chip according to the first embodiment.

FIG. 7 is a table illustrating an example of measurement conditions and operating currents stored in a storage circuit of a semiconductor chip according to a second embodiment.

FIG. 8 is a flowchart illustrating a flow of processes for storing operating temperatures and the operating currents in the semiconductor chip in a semiconductor package according to the second embodiment.

FIG. 9 is a diagram illustrating the operating temperatures and the operating currents stored in storage circuits of semiconductor chips in the second embodiment.

FIG. 10 is a flowchart illustrating an operation of controlling a current supplied to the semiconductor chip according to the second embodiment.

FIG. 11 is a table illustrating an example of measurement conditions and operating currents stored in a storage circuit of a semiconductor chip according to a third embodiment.

FIG. 12 is a flowchart illustrating a flow of processes for storing operating frequencies and the operating currents in the semiconductor chip in a semiconductor package according to the third embodiment.

FIG. 13 is a diagram illustrating the operating frequencies and the operating currents stored in storage circuits of semiconductor chips in the third embodiment.

FIG. 14 is a flowchart illustrating an operation of controlling a current supplied to the semiconductor chip according to the third embodiment.

FIG. 15 is a block diagram illustrating a connection configuration of a semiconductor package and a system control circuit according to a fourth embodiment.

FIG. 16 is a table illustrating operating frequencies, operating temperatures, and operating currents stored in a storage circuit of a semiconductor chip according to the fourth embodiment.

FIG. 17 is a flowchart illustrating an operation of controlling a current supplied to the semiconductor chip according to the fourth embodiment.

FIG. 18 is a diagram to explain a method for calculating operating currents of the semiconductor chip in a read operation according to the fourth embodiment.

FIG. 19 is a diagram to explain a method for calculating the operating frequencies corresponding to the currents supplied to the semiconductor chip according to the fourth embodiment.

FIG. 20 is a table illustrating an example of measurement conditions and operating currents stored in a storage circuit of a semiconductor chip according to a fifth embodiment.

FIG. 21 is a flowchart illustrating a flow of processes for storing the measurement conditions and the operating currents in the semiconductor chip in a semiconductor package according to the fifth embodiment.

FIG. 22 is a diagram illustrating the measurement conditions and the operating currents stored in storage circuits of semiconductor chips according to the fifth embodiment.

FIG. 23 is a flowchart illustrating an operation of controlling a current supplied to the semiconductor package according to the fifth embodiment.

FIG. 24 is a flowchart illustrating an operation of controlling a current supplied to a semiconductor package according to a sixth embodiment.

FIG. 25 is a diagram illustrating operating currents of a semiconductor chip and a generation rate of the operating currents.

FIG. 26 is a diagram illustrating an example of operating currents when a process is executed under the measurement conditions.

FIG. 27 is a diagram illustrating another example of operating currents when a process is executed under the measurement conditions.

FIG. 28 is a diagram illustrating another example of operating currents when a process is executed under the measurement conditions.

FIG. 29 is a diagram illustrating a total value of operating currents when two semiconductor chips are operating in parallel.

FIG. 30 is a diagram to explain an approximation and estimation method for obtaining operating currents.

FIG. 31 is a diagram to explain another approximation and estimation method for obtaining operating currents.

FIG. 32 is a diagram to explain still another approximation and estimation method for obtaining operating currents.

### DETAILED DESCRIPTION

Embodiments provide a semiconductor device capable of reducing operating currents.

In general, according to an embodiment, a semiconductor device includes a semiconductor circuit and a storage circuit. The semiconductor circuit consumes a first operating current when operating under a first operating condition and a second operating current when operating under a second operating condition. The second operating current is different from the first operating current. The storage circuit stores a correspondence between the first and second operating currents and the first and second operating conditions, respectively.

In the following description, components having the same function and configuration are denoted by a common reference numeral. Further, the embodiments described below exemplify devices and methods for embodying the technical idea of the embodiments, and materials, shapes, structures, arrangements, and the like of the components are not limited to those described below.

Functional blocks can be implemented as one of hardware and computer software, or a combination of both. It is not necessary that the functional blocks are distinguished as in the examples below. For example, some functions may be executed by functional blocks different from illustrated functional blocks. Furthermore, the illustrated functional blocks may be subdivided into finer functional sub-blocks.

Hereinafter, the embodiments will be described with reference to the drawings. The outline of the present application will be described in a first embodiment, and detailed aspects will be described in second to fifth embodiments.

### 1. First Embodiment

A semiconductor device according to a first embodiment and an information processing system including the semiconductor device will be described. In the first embodiment, values corresponding to operating currents obtained in a test performed on each of semiconductor chips in the semiconductor device is stored in each of the semiconductor chips from which the operating current is obtained. A current supplied to each of the semiconductor chips is controlled on the basis of the value corresponding to the operating current stored in each of the semiconductor chips. Hereinafter, the value corresponding to the operating current is simply referred to as an operating current.

### 1.1 Configuration of First Embodiment

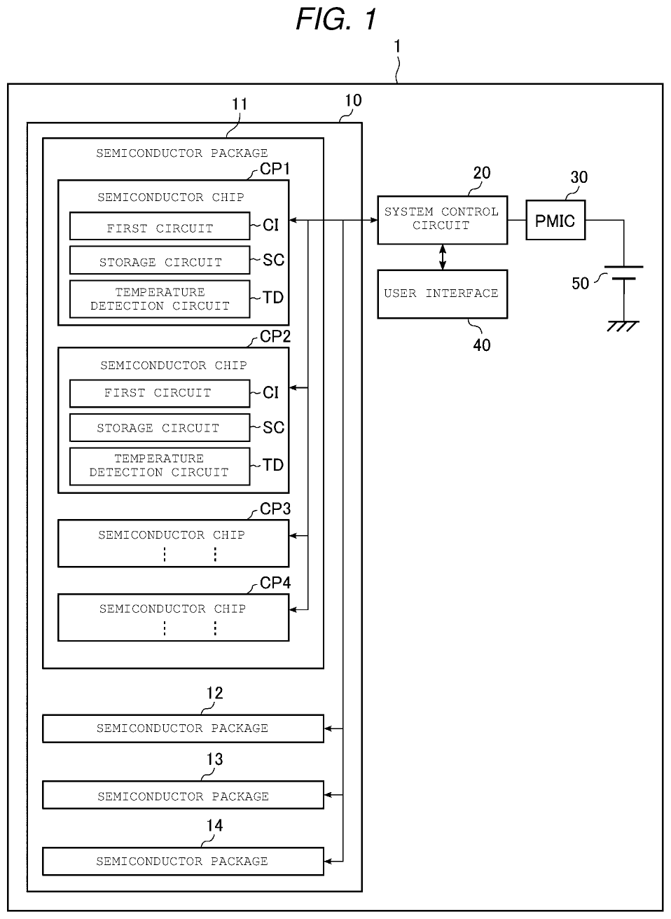

FIG. 1 is a block diagram illustrating a configuration of the information processing system including the semiconductor device according to the first embodiment. An information processing system 1 includes a semiconductor device 10, a system control circuit 20, a power management integrated circuit (PMIC) 30, a user interface 40, and a battery 50.

The semiconductor device 10 has one or a plurality of semiconductor packages. For example, the semiconductor device 10 has semiconductor packages 11, 12, 13, and 14. Each of the semiconductor packages 11 to 14 has one or a plurality of semiconductor chips. For example, each of the semiconductor packages 11 to 14 has semiconductor chips CP1, CP2, CP3, and CP4.

The semiconductor chips CP1 to CP4 may have the same function or may have different functions. Each of the semiconductor chips CP1 to CP4 includes, for example, a semiconductor storage device, a memory controller, a processor, or other integrated circuits. The semiconductor storage device includes, for example, a NAND flash memory, a static random access memory (SRAM), a dynamic random access memory (DRAM), or the like. The memory controller is a circuit that controls the semiconductor storage device. The processor performs an arithmetic process, control of devices in the information processing system 1, and the like. It is noted that, although each of the semiconductor packages 11 to 14 is described as having the same configuration, for example, having the semiconductor chips CP1, CP2, CP3, and CP4, the number of semiconductor chips provided in each of the semiconductor packages 11 to 14 may be different.

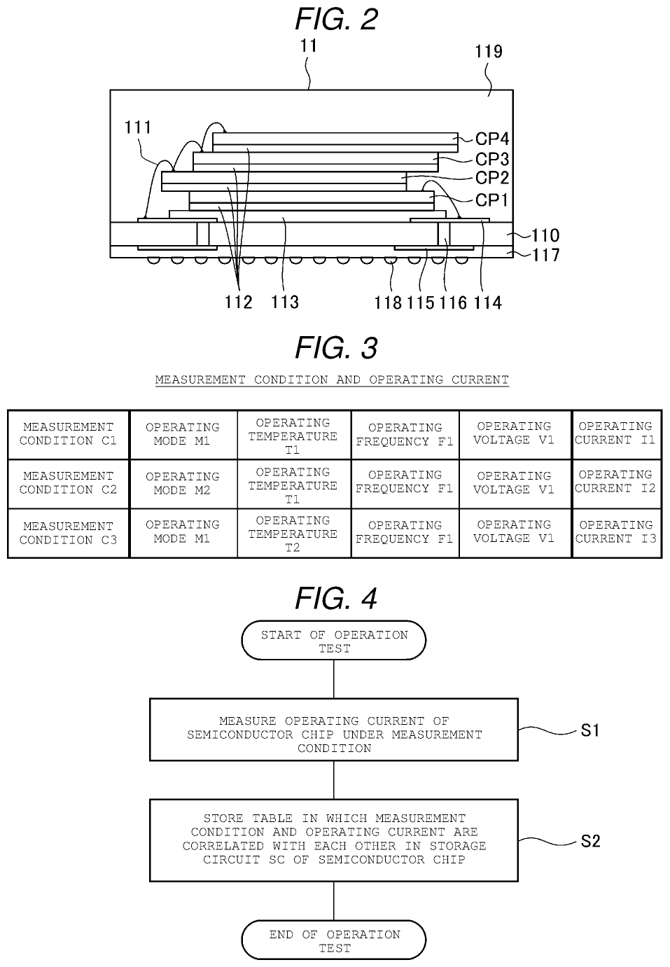

The semiconductor packages 11 to 14 will be described below with reference to FIGS. 1 and 2. Here, the semiconductor package 11 will be described as an example. It is noted that, in the following description, “upper” and “lower” correspond to an upward direction and a downward direction in each drawing, respectively.

FIG. 2 is a side view diagram (including a partial cross section) illustrating a configuration of the semiconductor package 11. The semiconductor package 11 has the semiconductor chips CP1 to CP4, a semiconductor substrate 110, bonding wires 111, insulating films 112, an insulating layer 113, pads 114 and 115, vias 116, an insulating layer 117, solder balls 118, and a molding material 119.

The insulating layer 113 is provided on the semiconductor substrate 110. The semiconductor chip CP1 is provided on the insulating layer 113 via the insulating films 112. The semiconductor chip CP2 is provided on the semiconductor chip CP1 via the insulating films 112. Similarly, the semiconductor chip CP3 is provided on the semiconductor chip CP2 via the insulating films 112. The semiconductor chip CP4 is provided on the semiconductor chip CP3 via the insulating films 112.

The pads 114 and 115 are provided on an upper surface and a lower surface of the semiconductor substrate 110, respectively. The bonding wires 111 are provided between the pads 114 and the semiconductor chip CP1 and between the pads 114 and the semiconductor chip CP2, respectively. Furthermore, the bonding wires 111 are provided between the semiconductor chips CP2, CP3, and CP4, respectively.

The insulating layer 117 is provided on the pads 115 of the semiconductor substrate 110. The solder balls 118 are provided on the pads 115 provided on the lower surface of the semiconductor substrate 110 and the pads (not illustrated), respectively. With the above configuration, the solder balls 118 are electrically connected to the semiconductor chips CP1 to CP4 via the pads 115, the vias 116, the pads 114, and the bonding wires 111.

The semiconductor chips CP1 to CP4 and the bonding wires 111 on the semiconductor substrate 110 are sealed by the molding material 119.

The semiconductor chips CP1 to CP4 will be described below. As illustrated in FIG. 1, the semiconductor chip CP1 has a first circuit CI, a storage circuit SC, and a temperature detection circuit TD. The first circuit CI is a circuit that implements desired functions and comprises a primary semiconductor component of the semiconductor chip CP1. The desired functions include, for example, a data storage, a control process, an arithmetic process, and the like. The storage circuit SC stores characteristics (or parameters) of the semiconductor chip CP1 (or the first circuit CI). The characteristics of the semiconductor chip CP1 include operating currents obtained (or generated) in an operation test for the semiconductor chip and measurement conditions (or operating conditions) of the operation test. It is noted that the first circuit CI and the storage circuit SC may be separately formed or integrally formed. For example, the first circuit may include the storage circuit SC.

Similarly to the semiconductor chips CP1, each of the semiconductor chips CP2 to CP4 has the first circuit CI, the storage circuit SC, and the temperature detection circuit TD. It is noted that, in some cases, one or plurality of semiconductor chips CP1 to CP4 may not have the temperature detection circuit TD. In this case, temperature detected by the temperature detection circuit TD of another semiconductor chip in the same package may be used.

FIG. 3 illustrates an example of the measurement conditions and the operating currents stored in the storage circuit SC of the semiconductor chip CP1. The measurement conditions are, for example, an operating mode, an operating temperature, an operating frequency, and an operating voltage (also an applied voltage).

The storage circuit SC of the semiconductor chip CP1 stores the measurement conditions and the operating currents in a table format in correlation with (in association with) each other. For example, as illustrated in FIG. 3, the storage circuit SC of the semiconductor chip CP1 stores an operating mode M1, an operating temperature T1, an operating frequency F1, and an operating voltage V1 as a measurement condition C1 and an operating current I1 obtained when the measurement condition C1 is set to the semiconductor chip CP1 in correlation with each other. Similarly, the storage circuit SC of the semiconductor chip CP1 stores an operating mode M2, the operating temperature T1, the operating frequency F1, and the operating voltage V1 as a measurement condition C2 and an operating current I2 obtained when the measurement condition C2 is set to the semiconductor chip CP1 in correlation with each other. The storage circuit SC of the semiconductor chip CP1 stores the operating mode M1, an operating temperature T2, the operating frequency F1, and the operating voltage V1 as a measurement condition C3 and an operating current I3 obtained when the measurement condition C3 is set to the semiconductor chip CP1 in correlation with each other.

It is noted that the measurement conditions and the operating currents illustrated in FIG. 3 are a portion of data included in the table stored in the storage circuit SC. Further, the storage circuit SC stores values (or data or parameters) corresponding to the operating mode, the operating temperature, the operating frequency, the operating voltage, and the operating currents, respectively. In the present specification, the operating mode, the operating temperature, the operating frequency, the operating voltage, and the operating currents are described as being stored.

As the operating mode, a plurality of operating modes can be set, respectively. For example, the plurality of operating modes include a write operation, a read operation, an arithmetic operation (for example, addition, subtraction, multiplication, or division), or a standby operation. The above-mentioned operating modes M1 or M2 represent one or a plurality of operations among the write operation, the read operation, the arithmetic operation, and the standby operation.

As the operating temperature, a plurality of operating temperatures can be set, respectively. The operating temperature is a temperature under an environment in which the semiconductor chip CP1 is expected to operate. In the measurement of the operating currents, an environmental temperature of the semiconductor chip CP1 is set as the operating temperature. The operating temperature includes, for example, a room temperature, a high temperature higher than the room temperature, and a low temperature lower than the room temperature. The above-mentioned operating temperature T1 or T2 represents one or a plurality of temperatures among the room temperature, the high temperature, and the low temperature.

As the operating frequency, a plurality of operating frequencies can be set, respectively. The operating frequency is a frequency of a clock signal that controls the operation of the semiconductor chip CP1. The above-mentioned operating frequency F1 represents one or more of different clock signals that can be set by the information processing system 1.

As the operating voltage, a plurality of operating voltages can be set, respectively. The operating voltage is a voltage in an operating standard to be supplied to the semiconductor chip CP1. The operating voltage V1 described above represents one or more of different operating voltages.

The operation of storing the operating mode, the operating temperature, the operating frequency, the operating voltage, and the operating currents thereof as the measurement conditions in the storage circuit SC of the semiconductor chip CP1 will be described below.

It is noted that the measurement conditions and the operating currents stored in the storage circuit SC of each of the semiconductor chips CP2 to CP4 are the same as those of the semiconductor chip CP1.

Returning to FIG. 1, the system control circuit 20 controls distribution of the currents supplied to the plurality of semiconductor chips (or the semiconductor packages) on the basis of the operating currents read from the storage circuits SC of the plurality of semiconductor chips (or the semiconductor chips in the semiconductor packages). According to such a control, the operation of the semiconductor chip is stopped, or operating performance of the semiconductor chip is optimized. Further, the operating frequency of the semiconductor chip is set to an optimum frequency according to the current supplied to the semiconductor chip. According to such setting, the operating currents consumed in the plurality of semiconductor chips (or semiconductor packages) can be reduced, and the operating performance of the semiconductor chip can be improved.

The PMIC 30 converts the voltage supplied from the battery 50 into an optimum operating voltage for the information processing system 1 and supplies the optimum operating voltage to the system control circuit 20. The PMIC 30 can also transmit a charge state of the battery 50 to the system control circuit 20. The PMIC 30 supplies and stops power to the system control circuit 20, the user interface 40, and the semiconductor device 10. The PMIC 30 also controls charging of the battery 50.

The user interface 40 is an interface for exchanging information between the information processing system 1 and a user. The user interface 40 is, for example, a key input device, a display, or the like.

The battery 50 is a device that stores electrical energy supplied from an external power source. The battery 50 supplies a power supply voltage for operating the information processing system 1.

It is noted that the number of semiconductor packages in the information processing system 1 is arbitrary, and may be more than or less than four. Further, the number of semiconductor chips in each of the semiconductor packages 11 to 14 is arbitrary, and may be more than or less than four.

### 1.2 Operation of First Embodiment

The operation of the information processing system 1 including the semiconductor device according to the first embodiment will be described.

First, the operation test for storing the operating mode, the operating temperature, the operating frequency, the operating voltage, and the operating currents thereof as the measurement conditions in the storage circuit SC of the semiconductor chip will be described. Here, the case of storing in the storage circuit SC of the semiconductor chips CP1 to CP4 in the semiconductor package 11 will be described as an example.

FIG. 4 is a flowchart illustrating a flow of processes of the operation test in which the measurement conditions and the operating currents are stored in the semiconductor chips CP1 to CP4 in the semiconductor package 11.

In the operation test, the plurality of measurement conditions C1, C2, . . . , Cn (n is a natural number of 1 or more) are set to the semiconductor chips CP1 to CP4, respectively, and respective operating currents of the semiconductor chips CP1 to CP4 under the measurement conditions C1 to Cn are measured, respectively (S1). For example, under the measurement condition C1, respective operating currents I1_1 to I1_4 of the semiconductor chips CP1 to CP4 are measured, respectively. Under the measurement condition C2, respective operating currents I2_1 to I2_4 of the semiconductor chips CP1 to CP4 are measured, respectively. Furthermore, under the measurement condition Cn, respective operating currents In_1 to In_4 of the semiconductor chips CP1 to CP4 are measured, respectively.

Next, the measurement condition Cn set in the operation test and the operating currents In_1 to In_4 measured in the respective semiconductor chips CP1 to CP4 are stored in the storage circuit SC of each of the semiconductor chips CP1 to CP4, respectively (S2).

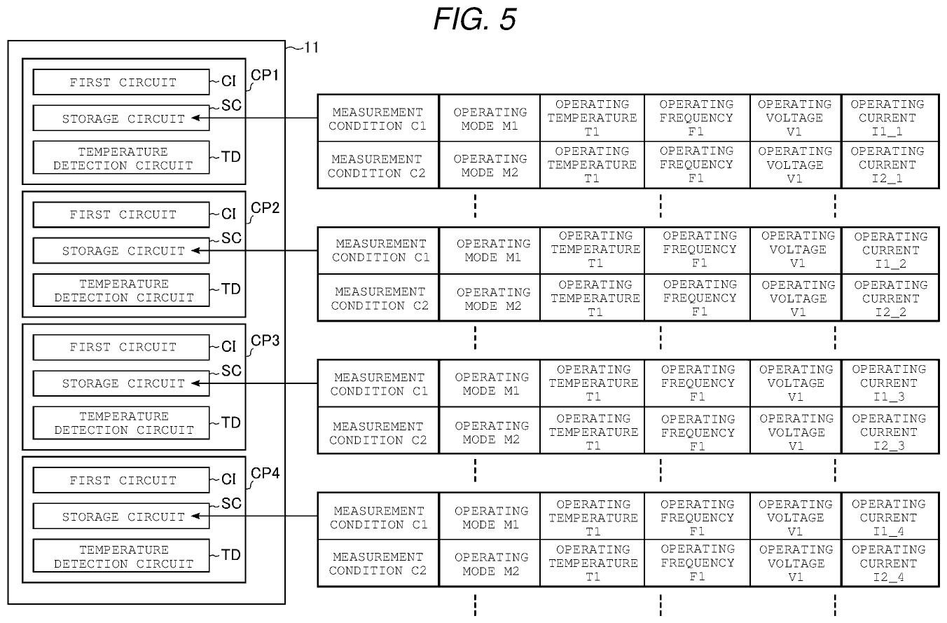

FIG. 5 illustrates the measurement condition Cn and the operating currents In_1 to In_4 stored in the storage circuit SC of each of the semiconductor chips CP1 to CP4. For example, the measurement condition C1 in the operation test and the operating current I1_1 measured in the semiconductor chip CP1 are stored in the storage circuit SC of the semiconductor chip CP1 in the table format as illustrated in FIG. 5. That is, the measurement condition C1 and the operating current I1_1 are stored in the storage circuit SC of the semiconductor chip CP1 in correlation with each other. The measurement condition C1 and the operating current I1_2 measured in the semiconductor chip CP2 are stored in the storage circuit SC of the semiconductor chip CP2 in the table format as illustrated in FIG. 5. That is, the measurement condition C1 and the operating current I1_2 are stored in the storage circuit SC of the semiconductor chip CP2 in correlation with each other. Similarly, the measurement condition C1 and the operating currents I1_3 and I1_4 measured in the semiconductor chips CP3 and CP4 are stored in the storage circuits SC of the semiconductor chips CP3 and CP4 in the table format as illustrated in FIG. 5, respectively.

It is noted that, similarly to the semiconductor package 11, as for the semiconductor packages 12 to 14, the measurement conditions and the operating currents are stored in the storage circuit SC of each of the semiconductor chips CP1 to CP4, respectively. With the above procedure, the operation test for the semiconductor chips in the semiconductor packages 11 to 14 is completed.

It is noted that a sorting test is also performed on the semiconductor chip, and in this sorting test, a product of which operating current falls between a determined lower limit value and a determined upper limit value is regarded as a non-defective product. The semiconductor chips in the semiconductor packages 11 to 14 are non-defective products in the sorting test. The measurement conditions and the operating currents in this sorting test can be used as the measurement conditions and the operating currents stored in the storage circuit SC of the semiconductor chip.

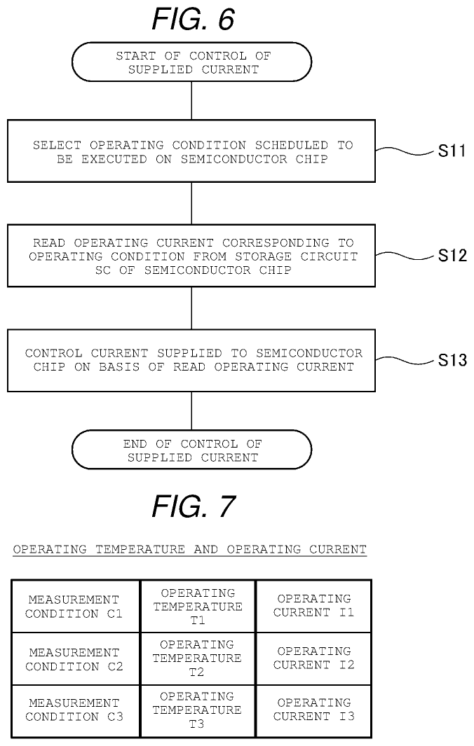

Next, an operation of controlling the currents supplied to the plurality of semiconductor chips in the semiconductor device 10 will be described. FIG. 6 is a flowchart illustrating the operation of controlling currents supplied to the plurality of semiconductor chips. This control is performed by the system control circuit 20.

First, the system control circuit 20 selects the operating conditions scheduled to be set among the operating conditions with which the information processing system 1 provides the semiconductor device 10 (S11). This operating condition corresponds to the measurement condition described above.

Next, the system control circuit 20 reads the operating currents corresponding to the operating conditions from the storage circuits SC of the semiconductor chips CP1 to CP4 in the semiconductor packages 11 to 14 (S12). More specifically, the system control circuit 20 finds the measurement condition that matches or approximates the operating condition set in step S11 from the storage circuit SC of the semiconductor chip and reads the operating current correlated with the measurement condition.

Next, the system control circuit 20 controls the currents supplied to the semiconductor chips CP1 to CP4 in the semiconductor packages 11 to 14 on the basis of the read operating currents (S13). More specifically, the system control circuit 20 distributes the currents supplied to the semiconductor chips CP1 to CP4 in the semiconductor packages 11 to 14 so that the semiconductor chips CP1 to CP4 in the semiconductor packages 11 to 14 can execute appropriate operations on the basis of the read operating currents in the current supply capacity allowed by the information processing system 1. The distribution of the currents by the system control circuit 20 denotes the following operations. The currents consumed by the semiconductor chips CP1 to CP4 are determined by the operating currents read from the storage circuits SC of the semiconductor chips CP1 to CP4 under the operating conditions selected by the system control circuit 20. “Distribution” is meant to supply the determined current to the semiconductor chips CP1 to CP4 and to supply a maximum current or an average current that each semiconductor chip may consume to the semiconductor chips CP1 to CP4. With the above procedure, the control of the currents supplied to the semiconductor chips in the semiconductor packages 11 to 14 is completed.

According to the above description, the operating currents consumed in the semiconductor chips CP1 to CP4 in the semiconductor packages 11 to 14 can be reduced. Furthermore, the semiconductor chips CP1 to CP4 in the semiconductor packages 11 to 14 can be efficiently operated in parallel. Accordingly, it is possible to improve the operating performance of the information processing system 1.

### 1.3 Effect of First Embodiment

According to the first embodiment, it is possible to provide the semiconductor device capable of reducing the operating currents.

Hereinafter, the effects of the first embodiment will be described. For example, in a mobile device or the like incorporating the semiconductor device, the operating performance of the semiconductor device and the performance of the user interface are changed according to the charge state of the battery. For example, when the charge state of the battery is lowered, the supplied current to the semiconductor device is reduced, the operating frequency of the semiconductor device is lowered, or brightness of a display screen of a display is lowered. For that reason, the operating current of the mobile device is reduced. This is to reduce the supplied current, the operating frequency, or the brightness predetermined in the mobile device when the charge state of the battery is lowered to a certain state. For this reason, in some cases, the operating performance of the semiconductor device in the mobile device may not be optimized, and the operating current may not be efficiently reduced.

According to the first embodiment, the semiconductor device (for example, the semiconductor chip or the semiconductor package) includes the storage circuit SC that stores the operating current of the semiconductor device. The storage circuit SC stores the operating conditions (or measurement conditions) and the operating currents consumed when the operating conditions are set to the semiconductor device in correlation with each other. The system control circuit 20 reads the operating currents corresponding to the operating conditions from the storage circuit SC. The system control circuit 20 supplies the appropriate currents for the operating conditions to the semiconductor device on the basis of the read operating currents. Accordingly, the current supply can be optimized, and the operating currents consumed in the semiconductor device can be reduced.

Further, according to the first embodiment, the consumption of the electric power stored in the battery 50 of the information processing system 1 can be reduced, and the operating time with the battery 50 can be lengthened. Accordingly, a charging interval to the battery 50 can be lengthened, and the number of times of charging the battery 50 can be reduced. As the result, it is possible to extend the lifetime of the battery 50.

Further, according to the first embodiment, the operating currents are read from the storage circuits SC of the plurality of semiconductor devices, and the appropriate currents for the operating conditions are supplied to the plurality of semiconductor devices on the basis of the read operating currents. Since the currents can be efficiently distributed to the plurality of semiconductor devices, the operating currents consumed in the plurality of semiconductor devices can be reduced. Furthermore, since the plurality of semiconductor devices can be operated in parallel, the operating performance of the information processing system 1 can be improved.

Further, by reducing the operating current of the semiconductor device, self-heating consumed in the semiconductor device can be lowered. An increase in temperature of the semiconductor device causes a decrease in reliability of the semiconductor device and the information processing system 1. For this reason, by preventing the increase in temperature of the semiconductor device, it is possible to prevent the decrease in reliability of the semiconductor device and the information processing system 1.

As the foregoing illustrates, according to the first embodiment, it is possible to provide the semiconductor device capable of reducing the operating currents.

### 2. Second Embodiment

A semiconductor device according to a second embodiment and an information processing system including the semiconductor device will be described. An operating current consumed in the semiconductor chip in the semiconductor device has an inherent correlation with the operating temperature in each of the semiconductor chips. In the second embodiment, the operating current of each of the semiconductor chips, which changes according to the operating temperature, is stored in each of the semiconductor chips in which the operating current is consumed. The current supplied to each of the semiconductor chips is controlled on the basis of the operating current stored in each of the semiconductor chips. Hereinafter, in the second embodiment, the aspects different from those of the first embodiment will be mainly described.

### 2.1 Configuration of Second Embodiment

A configuration of the information processing system 1 including the semiconductor device according to the second embodiment is the same as that of the first embodiment illustrated in FIGS. 1 and 2. In the second embodiment, the semiconductor package 11 will be described as an example. Further, it is assumed that the operating mode is set to be constant, and the operating frequency and the operating voltage are set in ranges that do not affect the operating current, respectively.

FIG. 7 illustrates an example of the measurement conditions and the operating currents stored in the storage circuit SC of the semiconductor chip CP1 in the semiconductor package 11. As the measurement conditions C1 to C3, the operating temperatures are set to T1, T2, and T3, respectively. The operating temperature T1 is a room temperature. T2 has a high temperature higher than the room temperature. T3 has a low temperature lower than the room temperature. Since the operating mode, the operating frequency, and the operating voltage are set to constant values or in ranges that do not affect the operating current, the operating mode, the operating frequency, and the operating voltage are omitted.

The storage circuit SC of the semiconductor chip CP1 stores the operating temperatures T1 to T3 and the operating currents thereof in the table format in correlation with each other. For example, as illustrated in FIG. 7, the storage circuit SC of the semiconductor chip CP1 stores the operating temperature T1 as the measurement condition C1 and the operating current I1 obtained when the operating temperature T1 is set to the semiconductor chip CP1 in correlation with each other. Similarly, the storage circuit SC of the semiconductor chip CP1 stores the operating temperature T2 as the measurement condition C2 and the operating current I2 obtained when the operating temperature T2 is set to the semiconductor chip CP1 in correlation with each other. Furthermore, the storage circuit SC of the semiconductor chip CP1 stores the operating temperature T3 as the measurement condition C3 and the operating current I3 obtained when the operating temperature T3 is set to the semiconductor chip CP1 in correlation with each other.

The semiconductor chips CP2 to CP4 in the semiconductor package 11 are the same as those of the semiconductor chip CP1. The storage circuit SC of each of the semiconductor chips CP2 to CP4 stores the operating temperatures T1 to T3 and the operating currents thereof in the table format in correlation with each other. Furthermore, the semiconductor packages 12 to 14 are the same as those of the semiconductor package 11. The storage circuit SC of each of the semiconductor chips CP1 to CP4 in the semiconductor packages 12 to 14 stores the operating temperatures T1 to T3 and the operating currents thereof in the table format in correlation with each other.

### 2.2 Operation of Second Embodiment

Operations of the information processing system 1 including the semiconductor device according to the second embodiment will be described.

First, the operation test for storing the operating temperature as the measurement condition and the operating current thereof in the storage circuit SC of the semiconductor chip will be described. Here, the case of storing in the storage circuit SC of the semiconductor chips CP1 to CP4 in the semiconductor package 11 will be described as an example.

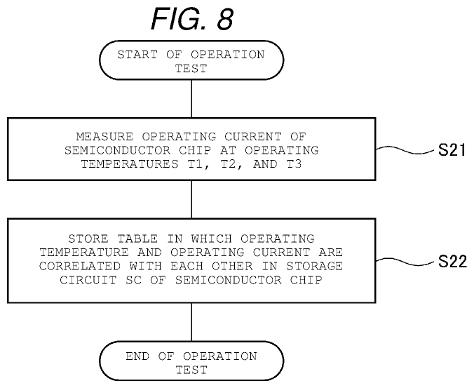

FIG. 8 is a flowchart illustrating a flow of processes of the operation test for storing the operating temperatures and the operating currents in the semiconductor chips CP1 to CP4 in the semiconductor package 11.

In the operation test, for example, the plurality of operating temperatures T1, T2, and T3 are set to the semiconductor chips CP1 to CP4, respectively, and respective operating currents of the semiconductor chips CP1 to CP4 at the operating temperatures T1 to T3 are measured, respectively (S21). For example, at the operating temperature T1, respective operating currents I1_1 to I1_4 of the semiconductor chips CP1 to CP4 are measured, respectively. At the operating temperature T2, respective operating currents I2_1 to I2_4 of the semiconductor chips CP1 to CP4 are measured, respectively. Furthermore, at the operating temperature T3, respective operating currents I3_1 to I3_4 of the semiconductor chips CP1 to CP4 are measured, respectively.

Next, the operating temperatures T1, T2, and T3 set in the operation test and the operating currents measured in each of the semiconductor chips CP1 to CP4 are stored in the storage circuit SC of each of the semiconductor chips CP1 to CP4, respectively (S22).

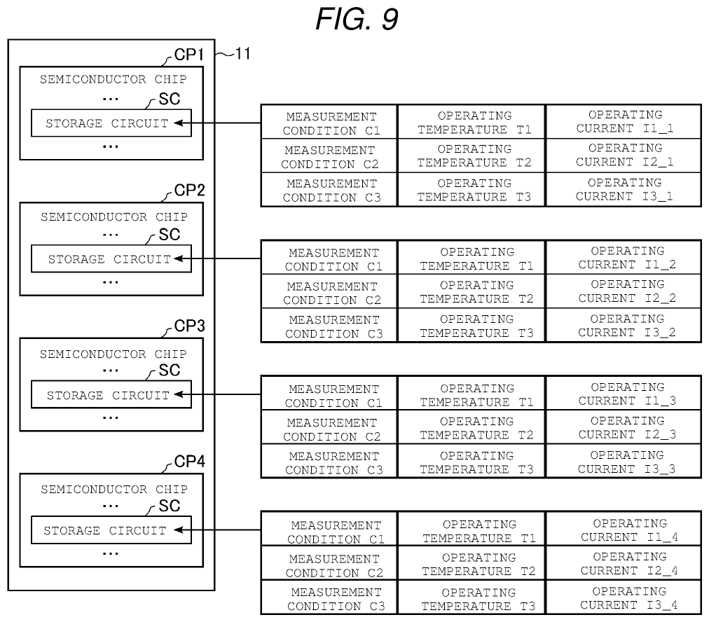

FIG. 9 illustrates the operating temperatures and the operating currents stored in the storage circuit SC of each of the semiconductor chips CP1 to CP4. For example, the operating temperature T1 in the operation test and the operating current I1_1 measured in the semiconductor chip CP1 are stored in the storage circuit SC of the semiconductor chip CP1 in the table format as illustrated in FIG. 9. That is, the operating temperature T1 and the operating current I1_1 are stored in the storage circuit SC of the semiconductor chip CP1 in correlation with each other. The operating temperature T1 and the operating current I1_2 measured in the semiconductor chip CP2 are stored in the storage circuit SC of the semiconductor chip CP2 in the table format as illustrated in FIG. 9. That is, the operating temperature T1 and the operating current I1_2 are stored in the storage circuit SC of the semiconductor chip CP2 in correlation with each other. Similarly, the operating temperature T1 and the operating currents I1_3 and I1_4 measured in the semiconductor chips CP3 and CP4 are stored in the storage circuits SC of the semiconductor chips CP3 and CP4 in the table format, respectively.

Similarly, the operating temperature T2 in the operation test and the operating currents I2_1 to I2_4 measured in the semiconductor chips CP1 to CP4 are stored in the storage circuits SC of the semiconductor chips CP1 to CP4 in the table format, respectively.

Furthermore, the operating temperature T3 in the operation test and the operating currents I3_1 to I3_4 measured in the semiconductor chips CP1 to CP4 are stored in the storage circuits SC of the semiconductor chips CP1 to CP4 in the table format, respectively.

It is noted that, similarly to the semiconductor packages 11, as for the semiconductor packages 12 to 14, the operating temperatures and the operating currents are stored in the storage circuit SC of each of the semiconductor chips CP1 to CP4 in correlation with each other, respectively. With the above procedure, the operation test for the semiconductor chips in the semiconductor packages 11 to 14 is completed.

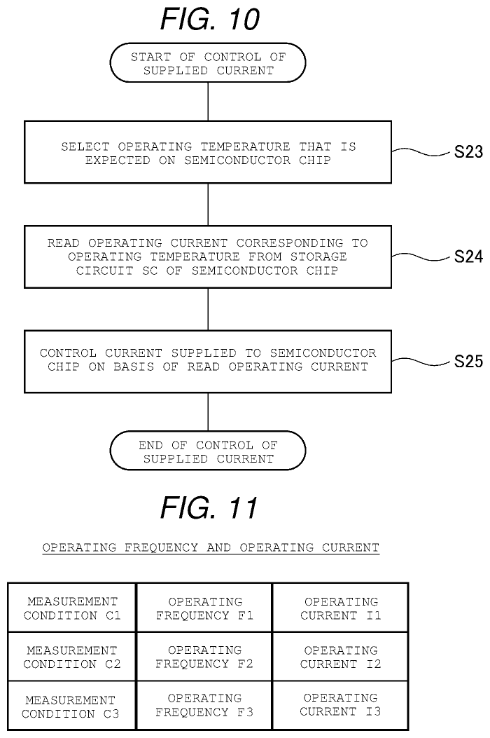

Next, an operation of controlling the currents supplied to the plurality of semiconductor chips in the semiconductor device 10 will be described. FIG. 10 is a flowchart illustrating the operation of controlling the currents supplied to the plurality of semiconductor chips. This control is performed by the system control circuit 20.

First, the system control circuit 20 selects the operating temperature that is expected set among the operating conditions with which the information processing system 1 provides the semiconductor device 10 (S23). This operating temperature corresponds to the operating temperature set as the measurement condition described above.

Next, the system control circuit 20 reads the operating currents corresponding to the operating temperatures from the storage circuits SC of the semiconductor chips CP1 to CP4 in the semiconductor packages 11 to 14 (S24). More specifically, the system control circuit 20 finds the operating temperature that matches or approximates the operating temperature set in step S23 from the storage circuit SC of the semiconductor chip, and reads the operating current correlated with the operating temperature.

Next, the system control circuit 20 controls the currents supplied to the semiconductor chips CP1 to CP4 in the semiconductor packages 11 to 14 on the basis of the read operating currents (S25). More specifically, the system control circuit 20 distributes the currents supplied to the semiconductor chips CP1 to CP4 in the semiconductor packages 11 to 14 so that the semiconductor chips CP1 to CP4 in the semiconductor packages 11 to 14 can execute appropriate operations on the basis of the read operating currents in the current supply capacity allowed by the information processing system 1. With the above procedure, the control of the currents supplied to the semiconductor chips in the semiconductor packages 11 to 14 is completed.

According to the above description, the operating currents consumed in the semiconductor chips CP1 to CP4 in the semiconductor packages 11 to 14 can be reduced. Furthermore, the semiconductor chips CP1 to CP4 in the semiconductor packages 11 to 14 can be efficiently operated in parallel. Accordingly, it is possible to improve the operating performance of the information processing system 1.

### 2.3 Effect of Second Embodiment

According to the second embodiment, it is possible to provide the semiconductor device capable of reducing the operating currents.

Hereinafter, the effects of the second embodiment will be described. In the second embodiment, the semiconductor device (for example, the semiconductor chip or the semiconductor package) includes the storage circuit SC that stores the operating current of the semiconductor device. The storage circuit SC stores the operating temperature and the operating current consumed when the operating temperature is set to the semiconductor device in correlation with each other. The system control circuit 20 reads the operating current corresponding to the operating temperature from the storage circuit SC. The system control circuit 20 supplies the appropriate current for the operating temperature to the semiconductor device on the basis of the read operating current. As a result, the current supply can be optimized, and the operating currents consumed in the semiconductor device can be reduced.

Further, according to the configuration of the second embodiment, the operating currents are read from the storage circuits SC of the plurality of semiconductor devices, and the appropriate currents for the operating temperatures are supplied to the plurality of semiconductor devices on the basis of the read operating currents. Since the currents can be efficiently distributed to the plurality of semiconductor devices, the operating currents consumed in the plurality of semiconductor devices can be reduced. Furthermore, since the plurality of semiconductor devices can be operated in parallel, the operating performance of the information processing system 1 can be improved. Other effects are the same as those in the first embodiment described above.

### 3. Third Embodiment

A semiconductor device according to a third embodiment and an information processing system including the semiconductor device will be described. An operating current consumed in the semiconductor chip in the semiconductor device corresponds with an operating frequency (or operating speed). In the third embodiment, the operating current of each of the semiconductor chips, which changes according to the operating frequency, is stored in each of the semiconductor chips in which the operating current is consumed. The current supplied to each of the semiconductor chips is controlled on the basis of the operating current stored in each of the semiconductor chips. Hereinafter, in the third embodiment, the aspects different from those of the first embodiment will be mainly described.

### 3.1 Configuration of Third Embodiment

A configuration of the information processing system 1 including the semiconductor device of the third embodiment is the same as that of the first embodiment illustrated in FIGS. 1 and 2. In the third embodiment, the semiconductor package 11 will be described as an example. Further, it is assumed that the operating mode is set to be constant, and the operating temperature and the operating voltage are set in ranges that do not affect the operating currents, respectively.

FIG. 11 illustrates an example of the measurement conditions and the operating currents stored in the storage circuit SC of the semiconductor chip CP1 in the semiconductor package 11. For example, the operating frequencies are set to F1, F2, and F3 as the measurement conditions C1 to C3, respectively. The operating mode, the operating temperature, and the operating voltage are omitted because the operating mode, the operating temperature, and the operating voltage are set to constant values or in ranges that do not significantly affect the operating currents.

The storage circuit SC of the semiconductor chip CP1 stores the operating frequencies F1 to F3 and the operating currents thereof in the table format in correlation with each other. For example, as illustrated in FIG. 11, the storage circuit SC of the semiconductor chip CP1 stores the operating frequency F1 as the measurement condition C1 and the operating current I1 obtained when the operating frequency F1 is set to the semiconductor chip CP1 in correlation with each other. Similarly, the storage circuit SC of the semiconductor chip CP1 stores the operating frequency F2 as the measurement condition C2 and the operating current I2 obtained when the operating frequency F2 is set to the semiconductor chip CP1 in correlation with each other. Furthermore, the storage circuit SC of the semiconductor chip CP1 stores the operating frequency F3 as the measurement condition C3 and the operating current I3 obtained when the operating frequency F3 is set to the semiconductor chip CP1 in correlation with each other.

The semiconductor chips CP2 to CP4 in the semiconductor package 11 are the same as those of the semiconductor chip CP1. The storage circuit SC of each of the semiconductor chips CP2 to CP4 stores the operating frequencies F1 to F3 and the operating currents thereof in the table format in correlation with each other. Furthermore, the semiconductor packages 12 to 14 are the same as those of the semiconductor package 11. The storage circuit SC of each of the semiconductor chips CP1 to CP4 in the semiconductor packages 12 to 14 stores the operating frequencies F1 to F3 and the operating currents thereof in the table format in correlation with each other.

### 3.2 Operation of Third Embodiment

Operations of the information processing system 1 including the semiconductor device according to the third embodiment will be described.

First, the operation test for storing the operating frequency as the measurement condition and the operating currents thereof in the storage circuit SC of the semiconductor chip will be described. Here, the case of storing in the storage circuit SC of the semiconductor chips CP1 to CP4 in the semiconductor package 11 will be described as an example.

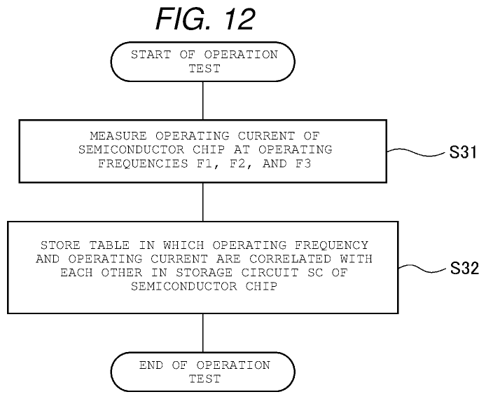

FIG. 12 is a flowchart illustrating a flow of processes of the operation test for storing the operating frequencies and the operating currents in the semiconductor chips CP1 to CP4 in the semiconductor package 11.

In the operation test, for example, the plurality of operating frequencies F1, F2, and F3 are set to the semiconductor chips CP1 to CP4, respectively, and the respective operating currents of the semiconductor chips CP1 to CP4 at the operating frequencies F1 to F3 are measured, respectively (S31). For example, at the operating frequency F1, the respective operating currents I1_1 to I1_4 of the semiconductor chips CP1 to CP4 are measured, respectively. At the operating frequency F2, the respective operating currents I2_1 to I2_4 of the semiconductor chips CP1 to CP4 are measured, respectively. Furthermore, at the operating frequency F3, the respective operating currents I3_1 to I3_4 of the semiconductor chips CP1 to CP4 are measured, respectively.

Next, the operating frequencies F1 to F3 set in the operation test and the operating currents measured in the respective semiconductor chips CP1 to CP4 are stored in the storage circuit SC of each of the semiconductor chips CP1 to CP4, respectively (S32).

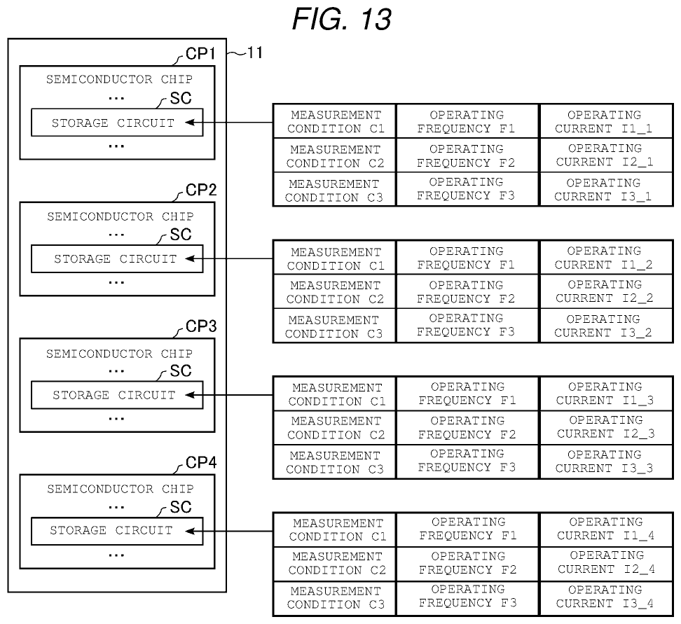

FIG. 13 illustrates the operating frequency and the operating currents stored in the storage circuit SC of each of the semiconductor chips CP1 to CP4. For example, the operating frequency F1 in the operation test and the operating current I1_1 measured in the semiconductor chip CP1 are stored in the storage circuit SC of the semiconductor chip CP1 in the table format as illustrated in FIG. 13. That is, the operating frequency F1 and the operating current I1_1 are stored in the storage circuit SC of the semiconductor chip CP1 in correlation with each other. The operating frequency F1 and the operating current I1_2 measured in the semiconductor chip CP2 are stored in the storage circuit SC of the semiconductor chip CP2 in the table format as illustrated in FIG. 13. That is, the operating frequency F1 and the operating current I1_2 are stored in the storage circuit SC of the semiconductor chip CP2 in correlation with each other. Similarly, the operating frequency F1 and the operating currents I1_3 and I1_4 measured in the semiconductor chips CP3 and CP4 are stored in the storage circuits SC of the semiconductor chips CP3 and CP4 in the table format, respectively.

Similarly, the operating frequency F2 in the operation test and the operating currents I2_1 to I2_4 measured in the semiconductor chips CP1 to CP4 are stored in the storage circuits SC of the semiconductor chips CP1 to CP4 in the table format, respectively.

Furthermore, the operating frequency F3 in the operation test and the operating currents I3_1 to I3_4 measured in the semiconductor chips CP1 to CP4 are stored in the storage circuits SC of the semiconductor chips CP1 to CP4 in the table format, respectively.

It is noted that, similarly to the semiconductor package 11, as for the semiconductor packages 12 to 14, the operating frequencies and the operating currents are stored in the storage circuit SC of each of the semiconductor chips CP1 to CP4 in correlation with each other, respectively. With the above procedure, the operation test for the semiconductor chips in the semiconductor packages 11 to 14 is completed.

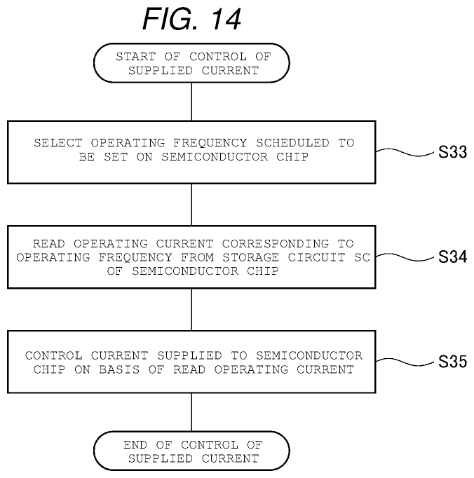

Next, an operation of controlling the currents supplied to the plurality of semiconductor chips in the semiconductor device 10 will be described. FIG. 14 is a flowchart illustrating the operation of controlling the currents supplied to the plurality of semiconductor chips. This control is executed by the system control circuit 20.

First, the system control circuit 20 selects the operating frequency scheduled to be set among the operating conditions with which the information processing system 1 provides the semiconductor device 10 (S33). This operating frequency corresponds to the operating frequency set as the measurement condition described above.

Next, the system control circuit 20 reads the operating currents corresponding to the operating frequencies from the storage circuits SC of the semiconductor chips CP1 to CP4 in the semiconductor packages 11 to 14 (S34). More specifically, the system control circuit 20 finds the operating frequency that matches or approximates the operating frequency set in step S33 from the storage circuit SC of the semiconductor chip and reads the operating current correlated with the operating frequency.

Next, the system control circuit 20 controls the currents supplied to the semiconductor chips CP1 to CP4 in the semiconductor packages 11 to 14 on the basis of the read operating currents (S35). More specifically, the system control circuit 20 distributes the currents supplied to the semiconductor chips CP1 to CP4 in the semiconductor packages 11 to 14 so that the semiconductor chips CP1 to CP4 in the semiconductor packages 11 to 14 can execute appropriate operations on the basis of the read operating currents in the current supply capacity allowed by the information processing system 1. With the above procedure, the control of the currents supplied to the semiconductor chips in the semiconductor packages 11 to 14 is completed.

According to the above description, the operating currents consumed in the semiconductor chips CP1 to CP4 in the semiconductor packages 11 to 14 can be reduced. Furthermore, the semiconductor chips CP1 to CP4 in the semiconductor packages 11 to 14 can be efficiently operated in parallel. Accordingly, it is possible to improve the operating performance of the information processing system 1.

### 3.3 Effect of Third Embodiment

According to the third embodiment, it is possible to provide the semiconductor device capable of reducing the operating currents.

Hereafter, the effects of the third embodiment will be described. In the third embodiment, the semiconductor device (for example, the semiconductor chip or the semiconductor package) includes the storage circuit SC that stores the operating currents of the semiconductor device. The storage circuit SC stores the operating frequency and the operating currents consumed when the operating frequency is set to the semiconductor device in correlation with each other. The system control circuit 20 reads the operating current corresponding to the operating frequency from the storage circuit SC. The system control circuit 20 supplies the appropriate current for the operating frequency to the semiconductor device on the basis of the read operating current. Accordingly, the current supply can be optimized, and the operating currents consumed in the semiconductor device can be reduced.

Further, according to the configuration of the third embodiment, the operating currents are read from the storage circuits SC of the plurality of semiconductor devices, and the appropriate currents for the operating frequencies are supplied to the plurality of semiconductor devices on the basis of the read operating currents. Since the currents can be efficiently distributed to the plurality of semiconductor devices, the operating currents consumed in the plurality of semiconductor devices can be reduced. Furthermore, since the plurality of semiconductor devices can be operated in parallel, the operating performance of the information processing system 1 can be improved. Other effects are the same as those in the first embodiment described above.

### 4. Fourth Embodiment

A semiconductor device according to a fourth embodiment and an information processing system including the semiconductor device will be described. In the fourth embodiment, the operation of controlling the supplied current to the plurality of semiconductor chips will be described in more detail. Hereinafter, in the fourth embodiment, the aspects different from those of the first embodiment will be mainly described.

### 4.1 Configuration of Fourth Embodiment

A configuration of the information processing system 1 including the semiconductor device according to the fourth embodiment is the same as that of the first embodiment illustrated in FIGS. 1 and 2. In the fourth embodiment, the semiconductor package 11 will be described as an example. As the measurement conditions (or operating conditions), the operating mode is set to the read operation, the operating temperature is set to a or b, the operating frequency is set to A or B, and the operating voltage is set in the range that does not affect the operating currents, respectively.

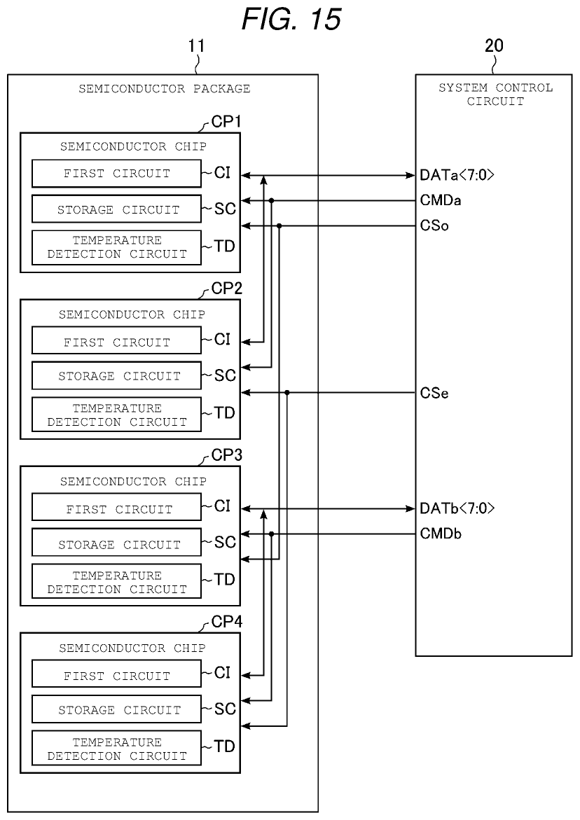

FIG. 15 is a block diagram illustrating a connection configuration between the semiconductor package 11 and the system control circuit 20 according to the fourth embodiment. The semiconductor package 11 and the system control circuit 20 in the semiconductor device 10 are connected by signal lines for transmitting and receiving chip select signals CSo and CSe, commands CMDa and CMDb, and data signals DATa and DATb.

The chip select signals CSo and CSe are signals for selecting the semiconductor chip. The system control circuit 20 outputs the chip select signal CSo to the odd-numbered semiconductor chips CP1 and CP3, and selects the semiconductor chips CP1 and CP3. The system control circuit 20 outputs the chip select signal CSe to the even-numbered semiconductor chips CP2 and CP4 and selects the semiconductor chips CP2 and CP4.

The commands CMDa and CMDb are signals that instruct the semiconductor chip to operate in an operating mode or execute a process. The command CMDa is output from the system control circuit 20 to the semiconductor chips CP1 and CP2 and allows the semiconductor chips CP1 and CP2 to operate in the operating mode or execute the process. The command CMDb is output from the system control circuit 20 to the semiconductor chips CP3 and CP4 and allows the semiconductor chips CP3 and CP4 to operate in the operating mode or execute the process.

The data signals DATa and DATb are signals including values, data or information and are, for example, signals including values corresponding to the operating currents or values corresponding to the temperatures. A data signal DATa<7:0> is a value, data or information transmitted/received between the system control circuit 20 and the semiconductor chips CP1 and CP2 and includes, for example, a value corresponding to the operating current stored in the storage circuit SC of the semiconductor chip CP1 or CP2 or a value corresponding to the temperature detected by the temperature detection circuit TD of the semiconductor chip CP1 or CP2. A data signal DATb<7:0> is a value, data or information transmitted/received between the system control circuit 20 and the semiconductor chips CP3 and CP4 and includes, for example, a value corresponding to the operating current stored in the storage circuit SC of the semiconductor chip CP3 or CP4 or a value corresponding to the temperature detected by the temperature detection circuit TD of the semiconductor chip CP3 or CP4.

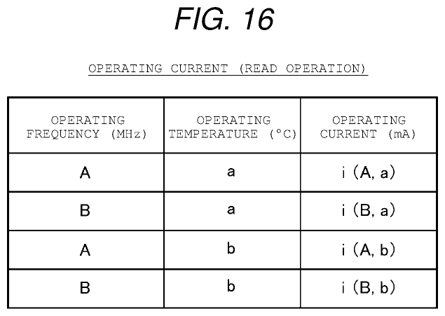

Further, the storage circuit SC of each of the semiconductor chips CP1 to CP4 stores the operating frequencies and the operating temperatures as the operating conditions and the operating currents. FIG. 16 illustrates the operating frequencies, the operating temperatures, and the operating currents stored in the storage circuit SC of the semiconductor chip CP1 in the semiconductor package 11.

For example, the storage circuit SC of the semiconductor chip CP1 stores the operating frequencies A and B and the operating temperatures a and b and the operating currents i obtained under these operating conditions in correlation with each other, respectively. More specifically, the storage circuit SC stores the operating frequency A and the operating temperature a and the operating current i(A,a) obtained under these operating conditions in correlation with each other. Similarly, the storage circuit SC stores the operating frequency B and the operating temperature a and the operating current i(B,a) obtained under these operating conditions in correlation with each other. The storage circuit SC stores the operating frequency A and the operating temperature b and the operating current i(A,b) obtained under these operating conditions in correlation with each other. Furthermore, the storage circuit SC stores the operating frequency B and the operating temperature b and the operating current i(B,b) obtained under these operating conditions in correlation with each other.

The semiconductor chips CP2 to CP4 in the semiconductor package 11 are the same as those of the semiconductor chip CP1. The storage circuit SC of each of the semiconductor chips CP2 to CP4 stores the operating frequencies A and B and the operating temperatures a and b and the operating currents i obtained under these operating conditions in correlation with each other, respectively. Furthermore, the semiconductor packages 12 to 14 are the same as those of the semiconductor package 11. The storage circuit SC of each of the semiconductor chips CP1 to CP4 in the semiconductor packages 12 to 14 stores the operating frequencies A and B and the operating temperatures a and b and the operating currents i obtained under these operating conditions in correlation with each other, respectively.

Further, the temperature detection circuit TD of each of the semiconductor chips CP1 to CP4 detects the temperature of each of the semiconductor chips CP1 to CP4 and transmits the detected temperature to the system control circuit 20.

### 4.2 Operation of Fourth Embodiment

Operations of the information processing system 1 including the semiconductor device according to the fourth embodiment will be described. Hereinafter, an operation of controlling the operating frequencies and the supplied currents with respect to the semiconductor chips CP1 to CP4 in the semiconductor package 11 will be described.

As illustrated in FIG. 16, the operating frequencies A and B, the operating temperatures a and b, and the operating currents i are stored in the storage circuits SC of the semiconductor chips CP1 to CP4 in the semiconductor package 11. Further, it is assumed that the operating conditions scheduled to be set (or currently being executed) are the operating frequency C and the operating temperature c.

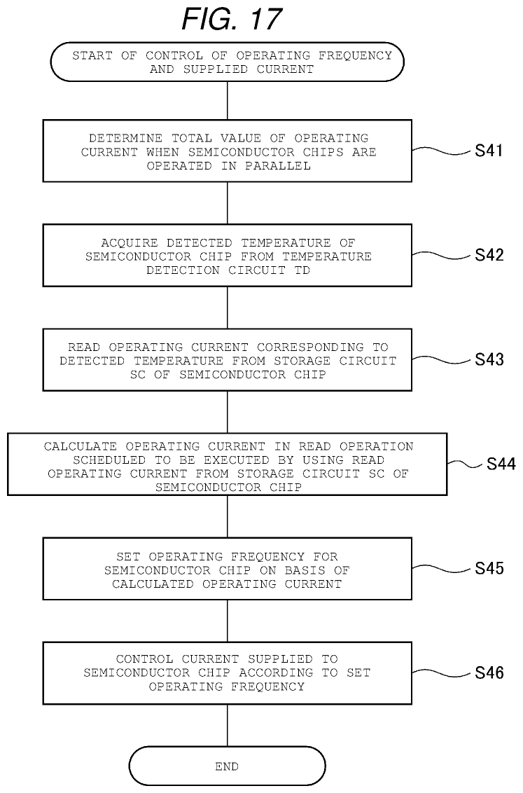

FIG. 17 is a flowchart illustrating the operation of controlling the operating frequencies and the supplied currents with respect to the semiconductor chips CP1 to CP4 in the semiconductor package 11. This control is performed by the system control circuit 20.

First, the system control circuit 20 determines a total value iTTL of the operating currents that can be tolerated when the semiconductor chips CP1 to CP4 in the semiconductor package 11 are operated in parallel (S41).

Next, the system control circuit 20 acquires the temperature (hereinafter referred to as the detected temperature) of each of the semiconductor chips CP1 to CP4 from the temperature detection circuits TD mounted on the semiconductor chips CP1 to CP4 (S42). The detected temperature corresponds to the operating temperature set as the measurement condition.

Next, the system control circuit 20 reads the operating currents corresponding to the operating temperature from the storage circuits SC of the semiconductor chips CP1 to CP4 by using the detected temperatures (that is, the operating temperatures) obtained from the temperature detection circuits TD (S43). More specifically, the system control circuit 20 finds the operating temperature that matches or approximates the detected temperature acquired in step S42 from the storage circuit SC of the semiconductor chip and reads the operating current correlated with the operating temperature.

It is noted that, to obtain the detected temperature and the operating current from the semiconductor chip, the semiconductor chip is selected with the chip select signal CSo or CSe. Furthermore, the command CMDa or CMDb allows the selected semiconductor chip to execute the output of the detected temperature and the output of the operating currents. Accordingly, the detected temperature and the operating currents can be obtained from the data signal DATa or DATb.

Here, when the operating temperatures stored in the storage circuits SC of the semiconductor chips CP1 to CP4 match the detected temperatures, the operating currents corresponding to the operating temperatures can be used as the operating current i(C,c) of the read operation scheduled to be executed. However, when the operating temperature stored in the storage circuit SC does not match the detected temperature, the operating current corresponding to the operating temperature approximate to the detected temperature is read out. Then, the operating current i(C,c) of the semiconductor chips CP1 to CP4 in the read operation scheduled to be executed is calculated by using the read operating currents by the following procedure according to an approximation method (S44).

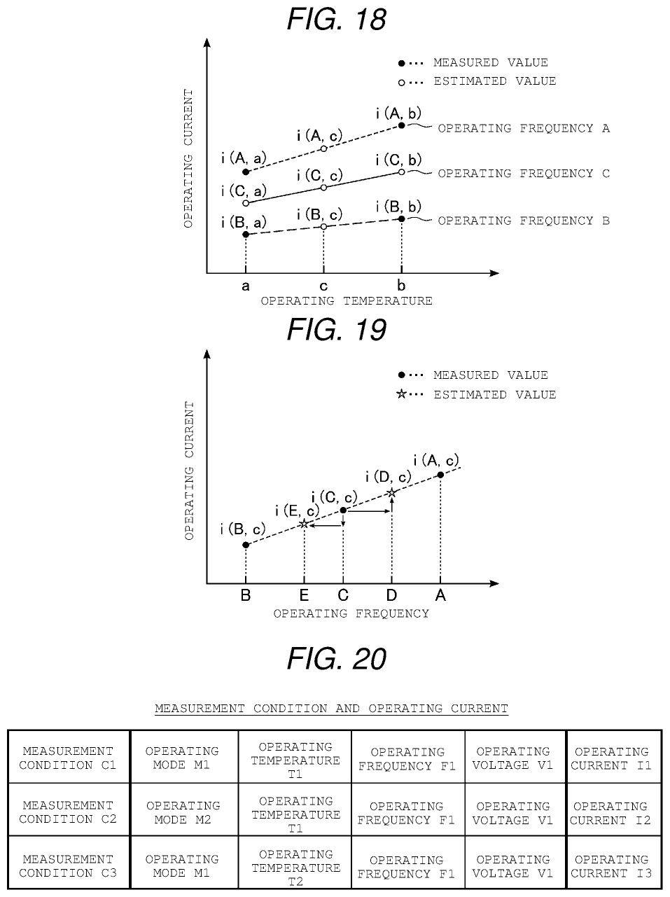

FIG. 18 illustrates a graph to explain a method for calculating the operating current i(C,c) of the semiconductor chip CP1 in the read operation scheduled to be executed. Specifically, the system control circuit 20 reads the operating current i(A,a) corresponding to the operating frequency A and the operating temperature a and the operating current i(B,a) corresponding to the operating frequency B and the operating temperature a from the storage circuit SC of the semiconductor chip CP1. Then, the system control circuit 20 obtains the operating current i(C,a) from the operating current i(A,a) and the operating current i(B,a).

Further, the system control circuit 20 reads the operating current i(A,b) corresponding to the operating frequency A and the operating temperature b and the operating current i(B,b) corresponding to the operating frequency B and the operating temperature b from the storage circuit SC of the semiconductor chip CP1. Then, the system control circuit 20 obtains the operating current i(C,b) from the operating current i(A,b) and the operating current i(B,b).

Furthermore, the system control circuit 20 obtains the operating current i(A,c) from the operating current i(A,b) and the operating current i(A,a). The system control circuit 20 obtains the operating current i(B,c) from the operating current i(B,b) and the operating current i(B,a). Then, the system control circuit 20 obtains the operating current i(C,c) from the operating current i(C,b) and the operating current i(C,a).

The system control circuit 20 performs such a process for obtaining the operating currents on the semiconductor chips CP2 to CP4 and obtains the respective operating currents i(A,c), i(B,c), and i(C,c) of the semiconductor chips CP2 to CP4.

Next, the system control circuit 20 sets the operating frequencies to the semiconductor chips CP1 to CP4 in the semiconductor package 11 on the basis of the respective operating currents i(A,c), i(B,c), and i(C,c) of the semiconductor chips CP1 to CP4 (S45).

Furthermore, the system control circuit 20 controls the currents supplied to the semiconductor chips CP1 to CP4 according to the operating frequencies set to the semiconductor chips CP1 to CP4 (S46).

Hereinafter, an operation of obtaining the operating frequencies and the supplied currents with respect to the semiconductor chip CP1 will be described on the basis of the operating currents i(A,c), i(B,c), and i(C,c) of the semiconductor chip CP1. For example, when the operating frequency D is set to the semiconductor chip CP1, the supplied current i(D,c) is supplied to the semiconductor chip CP1. The operating frequency D and the supplied current i(D,c) are calculated by the following procedure.

FIG. 19 illustrates a method for calculating the operating frequencies and the supplied currents on the basis of the operating currents of the semiconductor chip CP1. In FIG. 19, the horizontal axis represents the operating frequency, and the vertical axis represents the operating current.

A relationship between the operating frequencies A, B, and C at the operating temperature c and the operating currents i(A,c), i(B,c), and i(C,c) is illustrated as illustrated in FIG. 19. For example, when the operating frequency of the semiconductor chip CP1 is set to D or E, the supplied current i(D,c) or i(E,c) to the semiconductor chip CP1 in this case can be obtained from the graph illustrated in FIG. 19. Hereinafter, this will be described in detail.

Straight lines (hereinafter, estimated lines) connecting the operating currents i(B,c), i(C,c), and i(A,c) are drawn. When the operating frequency is set to D between C and A, the supplied current i(D,c) corresponding to the operating frequency D is plotted on the estimated line between the operating currents i(C,c) and i(A,c). On the other hand, when the operating frequency is set to E between C and B, the supplied current i(E,c) corresponding to the operating frequency E is plotted on the estimated line between the operating currents i(C,c) and i(B,c).

The system control circuit 20 sets the operating frequency D or E as the operating frequency that can be set by the information processing system 1 to the semiconductor chip CP1, and supplies the supplied current i(D,c) or i(E,c) in accordance with the operating frequency D or E to the semiconductor chip CP1.

The system control circuit 20 performs the above-described operation on each of the semiconductor chips CP1 to CP4. That is, the system control circuit 20 obtains the operating frequency D or E and the supplied current i(D,c) or i(E,c) with respect to each of the semiconductor chips CP1 to CP4 from the graph illustrated in FIG. 19. The system control circuit 20 sets the operating frequency D or E as the operating frequency that can be set by the information processing system 1 to the semiconductor chips CP1 to CP4 and supplies the supplied current i(D,c) or i(E,c) in accordance with the operating frequency D or E to the semiconductor chips CP1 to CP4. Here, when the supplied current is supplied to the semiconductor chips CP1 to CP4, the system control circuit 20 distributes the currents supplied to the semiconductor chips CP1 to CP4 so that a total value of the supplied currents to the semiconductor chips CP1 to CP4 falls in the total value iTTL determined in step S41.

With the above procedure, the setting of the operating frequency and the control of the supplied current with respect to the semiconductor chips CP1 to CP4 are completed.

It is noted that, in the above description, the currents supplied to the semiconductor chips CP1 to CP4 are controlled, but when the semiconductor chips CP1 to CP4 in the semiconductor package 11 have the same function, the current may be supplied to only one or the plurality of semiconductor chips having the lowest operating currents at the same operating frequency among the operating frequency, the operating temperature, and the operating current stored in the storage circuit SC of the semiconductor chip.

Also, by changing the setting of the operating frequency for each semiconductor chip, the change in the temperature of the semiconductor chip due to the self-heating occurs. For this reason, the system control circuit 20 acquires the temperatures and the operating currents from the semiconductor chip at a certain time interval. Then, on the basis of the acquired operating current, it is also possible to sequentially execute the setting of the operating frequency and the control of the supplied current with respect to the semiconductor chip.

Further, the operation of controlling the operating frequencies and the supplied currents with respect to the semiconductor chips CP1 to CP4 in the semiconductor packages 12 to 14 is the same as that of the semiconductor package 11. The operation of setting the operating frequency for the semiconductor chips CP1 to CP4 is executed for each of the semiconductor chips CP1 to CP4 of the semiconductor packages 12 to 14 in the same manner as described above, and furthermore, the operation of controlling the currents supplied to the semiconductor chips CP1 to CP4 is executed according to the operating frequency set to the semiconductor chips CP1 to CP4.

As the foregoing illustrates, the semiconductor chips CP1 to CP4 in the semiconductor packages 11 to 14 can be efficiently operated in parallel. Accordingly, it is possible to improve the operating performance of the information processing system 1.

### 4.3 Effect of Fourth Embodiment

According to the fourth embodiment, it is possible to provide the semiconductor device capable of reducing the operating currents.

Hereinafter, the effects of the fourth embodiment will be described. In the fourth embodiment, the semiconductor device (for example, the semiconductor chip or the semiconductor package) includes the storage circuit SC that stores the operating currents of the semiconductor device. The storage circuit SC stores the operating frequency and the operating temperature, and the operating frequency and the operating currents consumed when the operating frequency is set to the semiconductor device in correlation with each other. The system control circuit 20 acquires the detected temperature from the temperature detection circuit TD and reads the operating current corresponding to the detected temperature (that is, the operating temperature) from the storage circuit SC. The system control circuit 20 sets the operating frequency of the semiconductor device to an appropriate frequency on the basis of the read operating current. In other words, the processing speed (or operating speed) of the semiconductor device is set to an appropriate speed on the basis of the read operating current. Accordingly, it is possible to improve the operating performance of the semiconductor device. Furthermore, an appropriate current is supplied to the semiconductor device according to the set operating frequency. Accordingly, the current supply can be optimized, and the operating currents consumed in the semiconductor device can be reduced.

Further, according to the configuration of the fourth embodiment, the operating currents are read from the storage circuits SC of the plurality of semiconductor devices, and the operating frequencies of the plurality of semiconductor devices are set to the appropriate frequencies on the basis of the read operating currents. In other words, the processing speeds of the plurality of semiconductor devices are set to the appropriate speeds on the basis of the read operating currents. Accordingly, it is possible to improve the operating performance of the plurality of semiconductor devices. Furthermore, the appropriate currents are supplied to the plurality of semiconductor devices according to the set operating frequencies. Since the currents can be efficiently distributed to the plurality of semiconductor devices, the operating currents consumed in the plurality of semiconductor devices can be reduced. Other effects are the same as those in the first embodiment described above.

### 5. Fifth Embodiment

A semiconductor device according to a fifth embodiment and an information processing system including the semiconductor device will be described. In the first embodiment described above, the current supplied to each of the semiconductor chips is controlled. By contrast, in the fifth embodiment, the current supplied to the semiconductor package is controlled on the basis of the operating current of each of the semiconductor packages. The operating current in each of the semiconductor packages is a total current of the operating currents of the plurality of semiconductor chips in one semiconductor package. Hereinafter, in the fifth embodiment, the aspects different from those of the first embodiment will be mainly described.

### 5.1 Configuration of Fifth Embodiment

A configuration of the information processing system 1 including the semiconductor device according to the fifth embodiment is the same as that of the first embodiment illustrated in FIGS. 1 and 2.

The measurement conditions and the operating currents thereof are stored in the semiconductor chips in the respective semiconductor packages 11 to 14. For example, the measurement condition and the operating current thereof are stored in the storage circuit SC of the semiconductor chip CP1 in the semiconductor package 11. Similarly, the measurement condition and the operating current thereof are stored in the storage circuit SC of the semiconductor chip CP1 in each of the semiconductor packages 12 to 14. It is noted that the semiconductor chip in which the measurement conditions and the operating currents thereof are stored may be any one of the semiconductor chips CP1 to CP4 or may be a plurality of semiconductor chips.

FIG. 20 illustrates an example of the measurement conditions and the operating currents stored in the storage circuit SC of the semiconductor chip CP1 in the semiconductor package 11. The measurement conditions are, for example, the operating mode, the operating temperature, the operating frequency, and the operating voltage.

The storage circuit SC of the semiconductor chip CP1 in the semiconductor package 11 stores the measurement conditions and the operating currents thereof in the table format in correlation with each other. For example, as illustrated in FIG. 20, the storage circuit SC of the semiconductor chip CP1 stores the operating mode M1, the operating temperature T1, the operating frequency F1, and the operating voltage V1 as the measurement condition C1 and the operating current I1 obtained when the measurement condition C1 is set to the semiconductor chips CP1 to CP4 in the semiconductor package 11 in correlation with each other. Similarly, the storage circuit SC of the semiconductor chip CP1 stores the operating mode M2, the operating temperature T1, the operating frequency F1, and the operating voltage V1 as the measurement condition C2 and the operating current I2 obtained when the measurement condition C2 is set to the semiconductor chips CP1 to CP4 in the semiconductor package 11 in correlation with each other. The storage circuit SC of the semiconductor chip CP1 stores the operating mode M1, the operating temperature T2, the operating frequency F1, and the operating voltage V1 as the measurement condition C3 and the operating current 13 obtained when the measurement condition C3 is set to the semiconductor chips CP1 to CP4 in the semiconductor package 11 in correlation with each other.

It is noted that the measurement conditions and the operating currents illustrated in FIG. 20 are a portion of the table stored in the storage circuit SC.

### 5.2 Operation of Fifth Embodiment

Operations of the information processing system 1 including the semiconductor device according to the fifth embodiment will be described.

First, the operation test for storing the operating mode, the operating temperature, the operating frequency, the operating voltage, and the operating current thereof as the measurement conditions in the storage circuit SC of the semiconductor chip CP1 of each of the semiconductor packages 11 to 14 will be described. Here, the case of storing in the storage circuit SC of the semiconductor chip CP1 in the semiconductor package 11 will be described as an example.

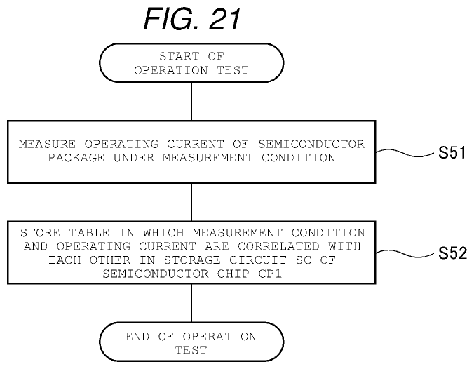

FIG. 21 is a flowchart illustrating a flow of processes of the operation test in which the measurement conditions and the operating currents are stored in the semiconductor chip CP1 in the semiconductor package 11.

In the operation test, the plurality of measurement conditions C1, C2, . . . , Cn are set to the semiconductor packages 11 to 14, respectively, and the respective operating currents of the semiconductor packages 11 to 14 under the measurement conditions C1 to Cn are measured, respectively (S51). For example, under the measurement condition C1, the respective operating currents I1_1 to I1_4 of the semiconductor packages 11 to 14 are measured, respectively. Under the measurement condition C2, the respective operating currents I2_1 to I2_4 of the semiconductor packages 11 to 14 are measured, respectively. Furthermore, under the measurement condition Cn, the respective operating currents In_1 to In_4 of the semiconductor packages 11 to 14 are measured, respectively.

Next, the measurement conditions Cl set in the operation test and the operating currents I1_1 to I1_4 measured in the respective semiconductor packages 11 to 14 are stored in the storage circuit SC of semiconductor chip CP1 in each of the semiconductor packages 11 to 14, respectively (S52).

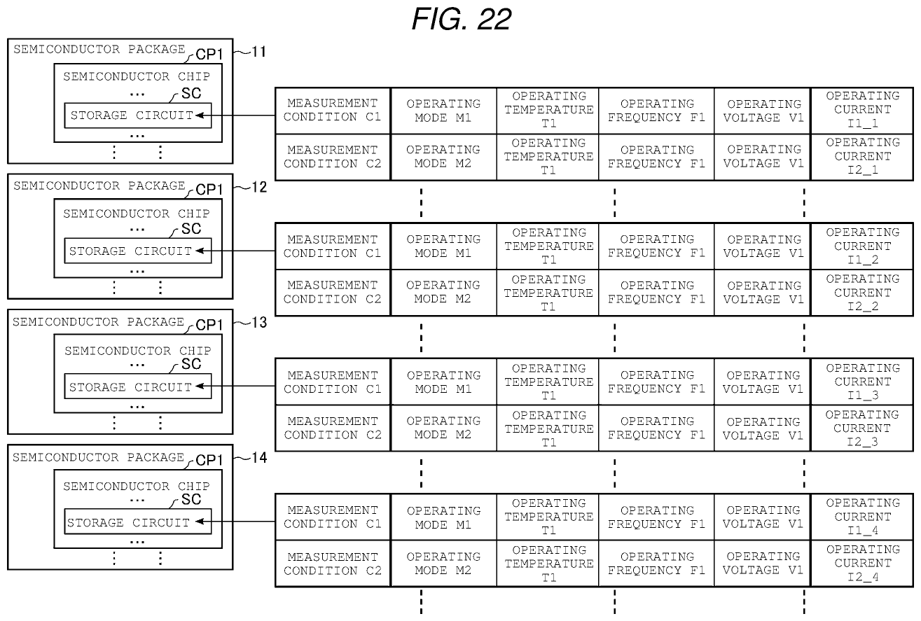

FIG. 22 illustrates the measurement condition Cn and the operating currents In_1 to In_4 stored in the storage circuit SC of the semiconductor chip CP1 of each of the semiconductor packages 11 to 14. For example, the measurement condition C1 in the operation test and the operating current I1_1 measured in the semiconductor package 11 are stored in the storage circuit SC of the semiconductor chip CP1 in the semiconductor package 11 in the table format as illustrated in FIG. 22. That is, the measurement condition C1 and the operating current I1_1 are stored in the storage circuit SC of the semiconductor chip CP1 in the semiconductor package 11 in correlation with each other. The measurement condition C1 and the operating current I1_2 measured in the semiconductor package 12 are stored in the storage circuit SC of the semiconductor chip CP1 in the semiconductor package 12 in the table format as illustrated in FIG. 22. That is, the measurement condition Cl and the operating current I1_2 are stored in the storage circuit SC of the semiconductor chip CP1 in the semiconductor package 12 in correlation with each other. Similarly, the measurement condition Cl and the operating currents I1_3 and I1_4 measured in the semiconductor packages 13 and 14 are stored in the storage circuit SC of the semiconductor chip CP1 of each of the semiconductor packages 13 and 14 in the table format as illustrated in FIG. 22, respectively. With the above procedure, the operation test for the semiconductor packages 11 to 14 is completed.

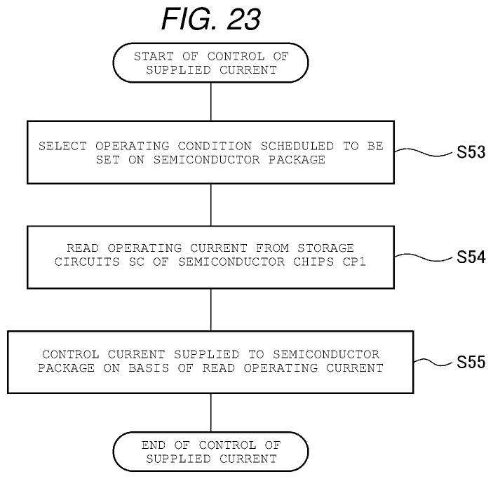

Next, an operation of controlling the currents supplied to the plurality of semiconductor packages in the semiconductor device 10 will be described. FIG. 23 is a flowchart illustrating the operation of controlling the currents supplied to the plurality of semiconductor packages. This control is performed by the system control circuit 20.

First, the system control circuit 20 selects the operating condition scheduled to be set among the operating conditions with which the information processing system 1 provides the semiconductor device 10 (S53). This operating condition corresponds to the measurement condition described above.

Next, the system control circuit 20 reads the operating currents corresponding to the operating conditions from the storage circuit SC of the semiconductor chip CP1 of each of the semiconductor packages 11 to 14 (S54). More specifically, the system control circuit 20 finds the measurement condition that matches or approximates the operating condition set in step S53 from the storage circuit SC of the semiconductor chip CP1 and reads the operating current correlated with the measurement condition.

Next, the system control circuit 20 controls the currents supplied to the semiconductor packages 11 to 14 on the basis of the read operating currents (S55). More specifically, the system control circuit 20 distributes the currents supplied to the semiconductor packages 11 to 14 so that the semiconductor packages 11 to 14 can execute appropriate operations on the basis of the read operating currents in the current supply capacity allowed by the information processing system 1. The distribution of the currents by the system control circuit 20 denotes the following operations. The current consumed by the semiconductor packages 11 to 14 is determined by the operating current read from the storage circuit SC of the semiconductor chip CP1 of the semiconductor packages 11 to 14 under the operating conditions selected by the system control circuit 20. “Distribution” is meant to supply the determined current to the semiconductor packages 11 to 14 and to supply the maximum current or the average current that each semiconductor package may consume to the semiconductor packages 11 to 14. With the above procedure, the control of the currents supplied to the semiconductor packages 11 to 14 is completed.

According to the above description, the operating currents consumed in the semiconductor packages 11 to 14 can be reduced. Furthermore, the semiconductor packages 11 to 14 can be efficiently operated in parallel. Accordingly, it is possible to improve the operating performance of the information processing system 1.

### 5.3 Effect of Fifth Embodiment

According to the fifth embodiment, it is possible to provide the semiconductor device capable of reducing the operating currents.

Hereinafter, the effects of the fifth embodiment will be described. In the fifth embodiment, the semiconductor package includes the storage circuit SC that stores the operating currents of the semiconductor package. The storage circuit SC stores the operating conditions (or measurement conditions) and the operating currents consumed when the operating conditions are set to the semiconductor device in correlation with each other. The system control circuit 20 reads the operating currents corresponding to the operating conditions from the storage circuit SC. The system control circuit 20 supplies the appropriate currents for the operating conditions on the basis of the read operating currents to the semiconductor package. Accordingly, the current supply can be optimized, and the operating currents consumed in the semiconductor package can be reduced.

Further, according to the configuration of the fifth embodiment, the operating current is read from the storage circuit SC of each of the plurality of semiconductor packages, and the appropriate currents for the operating conditions are supplied to the plurality of semiconductor packages on the basis of the read operating currents. Since the currents can be efficiently distributed to the plurality of semiconductor packages, the operating currents consumed in the plurality of semiconductor packages can be reduced. Furthermore, since the plurality of semiconductor packages can be operated in parallel, the operating performance of the information processing system 1 can be improved. Other effects are the same as those in the first embodiment described above.

### 6. Sixth Embodiment

A semiconductor device according to a sixth embodiment and an information processing system including the semiconductor device will be described. In the fourth embodiment described above, the current supplied to each of the semiconductor chips is controlled. By contrast, in the sixth embodiment, the current supplied to the semiconductor package is controlled on the basis of the operating current of each of the semiconductor packages. Hereinafter, in the sixth embodiment, the aspects different from those of the first and fourth embodiments will be mainly described.

### 6.1 Configuration of Sixth Embodiment

A configuration of the information processing system 1 including the semiconductor device according to the sixth embodiment is the same as that of the first embodiment illustrated in FIGS. 1 and 2 and that of the fourth embodiment illustrated in FIG. 15.

The measurement conditions and the operating currents thereof are stored in the semiconductor chip in each of the semiconductor packages 11 to 14. For example, as illustrated in FIG. 16, the operating frequency and the operating temperature as the measurement conditions and the operating currents thereof are stored in the storage circuit SC of the semiconductor chip CP1 in the semiconductor package 11. Similarly, the operating frequency and the operating temperature as the measurement conditions and the operating currents thereof are stored in the storage circuit SC of the semiconductor chip CP1 in each of the semiconductor packages 12 to 14. It is noted that the semiconductor chip in which the measurement conditions and the operating currents thereof are stored may be any one of the semiconductor chips CP1 to CP4 or may be the plurality of semiconductor chips CP1 to CP4.

### 6.2 Operation of Sixth Embodiment

Operations of the information processing system 1 including the semiconductor device according to the sixth embodiment will be described. Hereinafter, an operation of controlling the operating frequencies and the supplied currents with respect to the semiconductor packages 11 to 14 in the semiconductor device 10 will be described.

As illustrated in FIG. 16, the operating frequencies A and B, the operating temperatures a and b, and the operating currents i are stored in the storage circuit SC of the semiconductor chip CP1 of each of the semiconductor packages 11 to 14. In addition, the operating conditions scheduled to be set are assumed to be the operating frequency C and the operating temperature c.

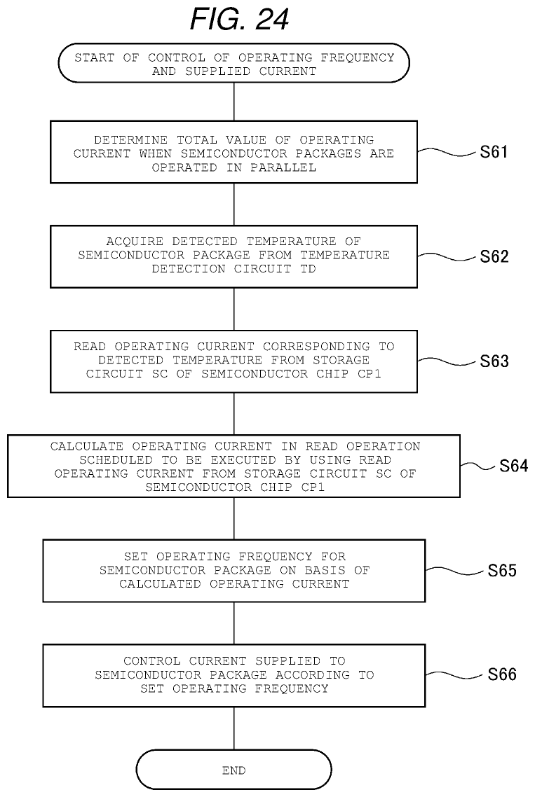

FIG. 24 is a flowchart illustrating the operation of controlling the operating frequencies and the supplied currents with respect to the semiconductor packages 11 to 14. This control is performed by the system control circuit 20.

First, the system control circuit 20 determines a total value iTTL of the operating currents that can be tolerated when the semiconductor packages 11 to 14 are operated in parallel (S61).

Next, the system control circuit 20 acquires the detected temperature of each of the semiconductor packages 11 to 14 from the temperature detection circuit TD mounted on the semiconductor chips CP1 of each of the semiconductor packages 11 to 14 (S62). The detected temperature corresponds to the operating temperature set as the measurement condition.

Next, the system control circuit 20 reads the operating current corresponding to the operating temperature from the storage circuit SC of the semiconductor chip CP1 by using the detected temperature (that is, the operating temperature) obtained from the temperature detection circuit TD (S63). More specifically, the system control circuit 20 finds the operating temperature that matches or approximates the detected temperature acquired in step S62 from the storage circuit SC of the semiconductor chip CP1 and reads the operating current correlated with the operating temperature.

Here, when the operating temperature stored in the storage circuit SC of the semiconductor chip CP1 matches the detected temperature, the operating current corresponding to the operating temperature can be used as the operating current i(C,c) of the read operation scheduled to be executed. However, when the operating temperature stored in the storage circuit SC does not match the detected temperature, the operating current corresponding to the operating temperature approximate to the detected temperature is read out. Then, the operating current i(C,c) of the semiconductor packages 11 to 14 in the read operation scheduled to be executed is calculated by using the read operating currents by the following procedure according to an approximation method (S64).

The system control circuit 20 reads the operating current i(A,a) corresponding to the operating frequency A and the operating temperature a and the operating current i(B,a) corresponds to the operating frequency B and the operating temperature a from the storage circuit SC of the semiconductor chip CP1 in the semiconductor package 11. Then, as illustrated in FIG. 18, the system control circuit 20 obtains the operating current i(C,a) from the operating current i(A,a) and the operating current i(B,a).

Further, the system control circuit 20 reads the operating current i(A,b) corresponding to the operating frequency A and the operating temperature b and the operating current i(B,b) corresponding to the operating frequency B and the operating temperature b from the storage circuit SC of the semiconductor chip CP1 in the semiconductor package 11. Then, as illustrated in FIG. 18, the system control circuit 20 obtains the operating current i(C,b) from the operating current i(A,b) and the operating current i(B,b).

Furthermore, as illustrated in FIG. 18, the system control circuit 20 obtains the operating current i(A,c) from the operating current i(A,b) and the operating current i(A,a). The system control circuit 20 obtains the operating current i(B,c) from the operating current i(B,b) and the operating current i(B,a). Then, the system control circuit 20 obtains the operating current i(C,c) from the operating current i(C,b) and the operating current i(C,a).

The system control circuit 20 performs such an operation of obtaining the operating currents on the semiconductor packages 12 to 14, and the respective operating currents i(A,c), i(B,c), and i(C,c) of the semiconductor packages 11 to 14.

Next, the system control circuit 20 sets the operating frequencies to the semiconductor packages 11 to 14 on the basis of the respective operating currents i(A,c), i(B,c), and i(C,c) of the semiconductor packages 11 to 14 (S65).

Furthermore, the system control circuit 20 controls the currents supplied to the semiconductor packages 11 to 14 according to the operating frequencies set to the semiconductor packages 11 to 14 (S66).

Hereinafter, an operation of obtaining the operating frequency and the supplied current with respect to the semiconductor package 11 on the basis of the operating currents i(A,c), i(B,c), and i(C,c) of the semiconductor package 11 will be described. For example, when the operating frequency D is set to the semiconductor package 11, the supplied current i(D,c) is supplied to the semiconductor package 11. The operating frequency D and the supplied current i(D,c) are calculated by the following procedure.

As described above, the relationship between the operating frequencies A, B, and C and the operating currents i(A,c), i(B,c), i(C,c) at the operating temperature c is illustrated as in FIG. 19. For example, when the operating frequency of the semiconductor package 11 is set to D or E, the supplied current i(D,c) or i(E,c) to the semiconductor package 11 in this case can be obtained from the graph illustrated in FIG. 19. Hereinafter, this will be described in detail.

Straight lines (hereinafter, estimated lines) connecting the operating currents i(B,c), i(C,c), and i(A,c) are drawn. When the operating frequency is set to D between C and A, the supplied current i(D,c) corresponding to the operating frequency D is plotted on the estimated line between the operating currents i(C,c) and i(A,c). On the other hand, when the operating frequency is set to E between C and B, the supplied current i(E,c) corresponding to the operating frequency E is plotted on the estimated line between the operating currents i(C,c) and i(B,c).

The system control circuit 20 sets the operating frequency D or E as the operating frequency that can be set by the information processing system 1 to the semiconductor package 11 and supplies the supplied current i(D,c) or i(E,c) in accordance with the operating frequency D or E to the semiconductor package 11.

The system control circuit 20 performs the above-described operation on each of the semiconductor packages 11 to 14. That is, the system control circuit 20 obtains the operating frequency D or E and the supplied current i(D,c) or i(E,c) with respect to each of the semiconductor packages 11 to 14 from the graph illustrated in FIG. 19. The system control circuit 20 sets the operating frequency D or E as the operating frequency that can be set by the information processing system 1 to the semiconductor packages 11 to 14 and supplies the supplied current i(D,c) or i(E,c) in accordance with the operating frequency D or E to the semiconductor packages 11 to 14. Here, when the supplied current is supplied to the semiconductor packages 11 to 14, the system control circuit 20 distributes the currents supplied to the semiconductor packages 11 to 14 so that a total value of the supplied currents to the semiconductor packages 11 to 14 falls in the total value iTTL determined in step S61.

With the above procedure, the setting of the operating frequency and the control of the supplied current with respect to the semiconductor packages 11 to 14 are completed.

It is noted that, by changing the setting of the operating frequency for each semiconductor package, the change in the temperature of the semiconductor package due to the self-heating occurs. For this reason, the system control circuit 20 acquires the temperatures and the operating currents from the semiconductor chip of the semiconductor package at a certain time interval. Then, on the basis of the acquired operating currents, it is also possible to sequentially execute the setting of the operating frequency and the control of the supplied current with respect to the semiconductor package.

As the foregoing illustrates, it is possible to efficiently operate the semiconductor packages 11 to 14 in parallel. Accordingly, it is possible to improve the operating performance of the information processing system 1.

### 6.3 Effect of Sixth Embodiment

According to the sixth embodiment, it is possible to provide the semiconductor device capable of reducing the operating currents.

Hereinafter, the effects of the sixth embodiment will be described. In the sixth embodiment, the semiconductor package includes the storage circuit SC that stores the operating currents of the semiconductor package. The storage circuit SC stores the operating frequency and the operating temperature, and the operating frequency and the operating current consumed when the operating frequency is set to the semiconductor device in correlation with each other. The system control circuit 20 acquires the detected temperature from the temperature detection circuit TD and reads the operating current corresponding to the detected temperature (that is, the operating temperature) from the storage circuit SC. The system control circuit 20 sets the operating frequency of the semiconductor package to an appropriate frequency on the basis of the read operating current. In other words, the system control circuit 20 sets a processing speed (or operating speed) of the semiconductor package to an appropriate speed on the basis of the read operating current. Accordingly, it is possible to improve the operating performance of the semiconductor package. Furthermore, an appropriate current is set to the semiconductor package according to the set operating frequency. Accordingly, the current supply can be optimized, and the operating current consumed in the semiconductor package can be reduced.

Further, according to the configuration of the sixth embodiment, the operating currents are read from the storage circuits SC of the plurality of semiconductor packages, and the operating frequencies of the plurality of semiconductor packages are set to the appropriate frequencies on the basis of the read operating currents. In other words, the processing speeds of the plurality of semiconductor packages are set to appropriate speeds on the basis of the read operating currents. Accordingly, it is possible to improve the operating performance of the plurality of semiconductor packages. Furthermore, the appropriate currents are supplied to the plurality of semiconductor packages according to the set operating frequencies. Since the currents can be efficiently distributed to the plurality of semiconductor packages, the operating currents consumed in the plurality of semiconductor packages can be reduced. Other effects are the same as those in the first embodiment described above.

### 7. Method for Obtaining Operating currents

In a manufacturing process of the semiconductor device, a silicon wafer on which an electronic circuit is formed thereon or a semiconductor chip that is obtained by dividing the silicon wafer into pieces and enclosing one or more pieces in a semiconductor package is formed. The sorting test is performed on the silicon wafer or the semiconductor chip in a semiconductor package state using a semiconductor tester under the plurality of measurement conditions.

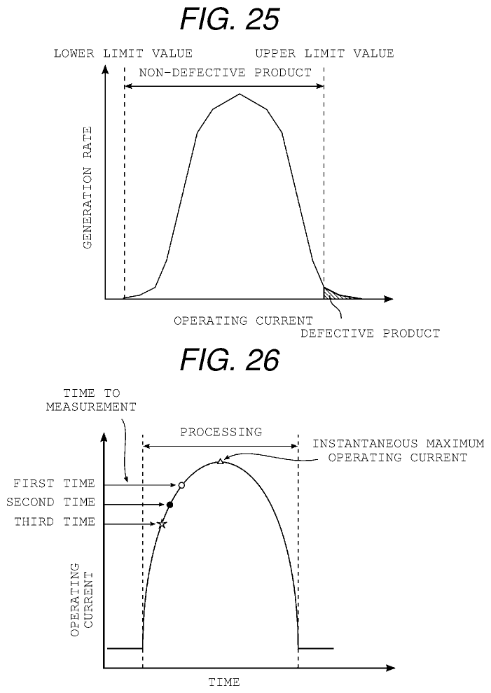

In this sorting test, the plurality of semiconductor chips are set under certain measurement conditions, and the operating current consumed in each of the semiconductor chips is measured. FIG. 25 illustrates the operating currents of the semiconductor chip and a consumption rate of the operating currents. As illustrated in FIG. 25, a non-defective product is considered to have an operating current between a determined lower limit value and a determined upper limit value.

As described above, the measurement conditions and the operating currents thereof in such a sorting test can be used as the measurement conditions and the operating currents to be stored in the storage circuit SC of the semiconductor chip in the embodiment. Furthermore, it is also possible to execute another operation test and use the measurement conditions and the operating currents obtained in the test as the measurement conditions and the operating currents to be stored in the storage circuit SC.

Hereinafter, a method for obtaining the operating currents of the semiconductor chip described in the above-described embodiment will be described.

FIGS. 26, 27, and 28 illustrate the operating currents when a process (for example, read operation) is executed under certain measurement conditions. The operating currents may be obtained by one time of measurement during the process under the certain measurement conditions, or as illustrated in FIG. 26, the operating currents may be obtained by a plurality of times (for example, the first, second, and third times) of measurement while repeating the process.

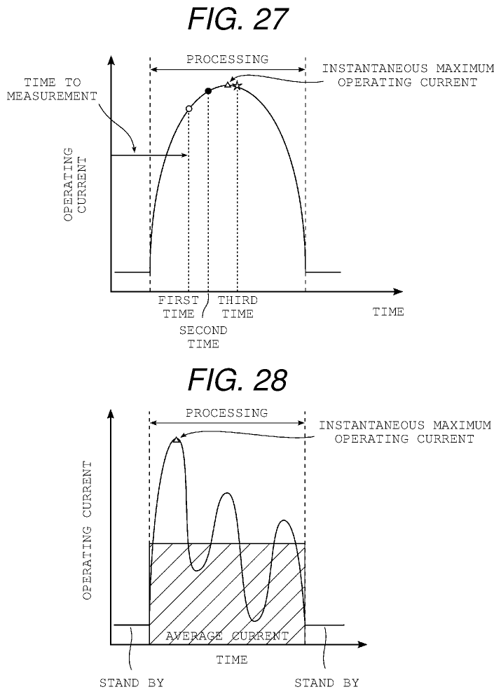

Further, as illustrated in FIG. 27, the operating currents may be obtained by a plurality of times (for example, the first, second, and third times) of measurement during one process under the certain measurement conditions. In this measurement, the operating currents are measured by changing a time from a start (the command issue time from the system control circuit 20) of the process to the measurement. In this case, the average of the plurality of values obtained in three times of the measurement can be used as the operating currents. Alternatively, a point (third point in FIG. 27) at which the operating current obtained by the measurement becomes maximum can be used as a maximum operating current.

Further, as illustrated in FIG. 28, the operating currents may be obtained by measuring the average current for a certain period with a current waveform during one process. Accordingly, it is possible to improve the accuracy of the operating current obtained by the measurement.

These measurement methods are determined by length of a time required for the test, costs associated with the time, a performance of a semiconductor tester used for the test, and the like.

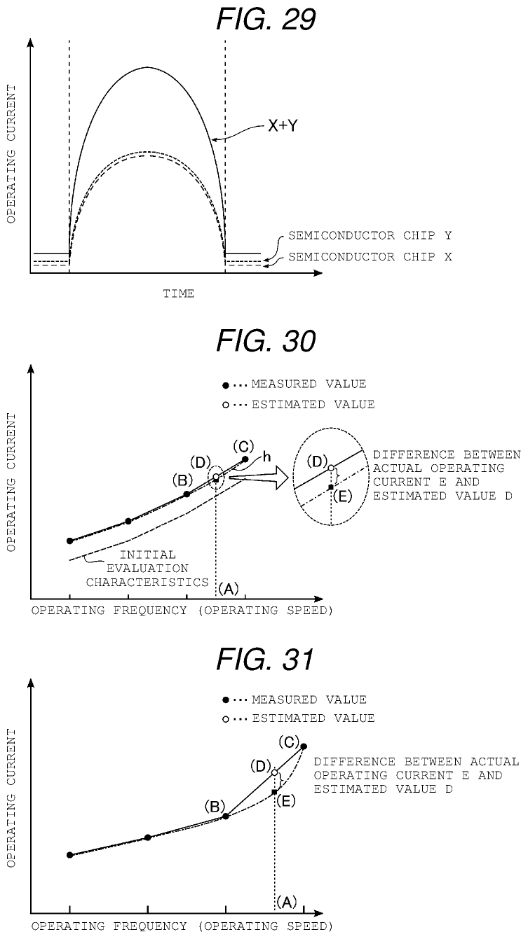

Next, the operating currents of the semiconductor package including the plurality of semiconductor chips will be described. In the semiconductor package in which the plurality of semiconductor chips are enclosed, when the plurality of semiconductor chips in the semiconductor package are operated in parallel or when several semiconductor chips are allowed to stand by, the operating current becomes the total value of the respective operating currents of the semiconductor chips that are operating. FIG. 29 illustrates the total value of the operating currents when two semiconductor chips X and Y are operating in parallel.

In a case of the semiconductor package, the measurement condition and the operating current are stored in the storage circuit SC of one of the plurality of semiconductor chips in the semiconductor package. Alternatively, the measurement condition and the operating current may be stored in the storage circuit SC of each of the plurality of semiconductor chips in the semiconductor package, respectively. When the measurement conditions and the operating currents are stored in the storage circuit SC of each of the semiconductor chips, the system control circuit 20 reads the measurement conditions and the operating currents from each storage circuit SC, totals the read operating currents, and uses the total operating current as the operating currents of the semiconductor package.

Further, when the desired operating currents cannot be obtained from the measurement conditions (or operating conditions) and the operating currents stored in the storage circuit SC of the semiconductor chip, the system control circuit 20 can obtain the operating currents by using the following approximation and estimation method. Here, in order to reduce the load to the system control circuit 20, a method for interpolating the operating currents read from the storage circuit SC, that is, the operating currents obtained by the measurement at the time of the test by linear approximation will be described.

It is known from an initial evaluation of the semiconductor chip that the electrical characteristics (for example, the operating currents with respect to the operating frequency or the operating temperature) of the semiconductor chip take the profile and the tendency as illustrated by the broken line in FIG. 30. From the measured values (black dots) in the sorting test for the semiconductor chips, it can be estimated that the electrical characteristics of the semiconductor chip are estimated from initial evaluation characteristics (broken line) and illustrated by the one-dot chain line h. Here, by interpolating the operating current at an operating frequency (A) as the operating condition from measured values (B) and (C) at a time of the sorting test to the straight line, a value at a point (D) (white circle) can be obtained. Actually, the operating current at the operating frequency (A) of the corresponding semiconductor chip is a point (E) (black square) and is expected to be on the one-dot chain line h. When a difference between the values at the points (D) and (E) is allowable as the information processing system, the operating current at the point (D) obtained by this approximation is used.

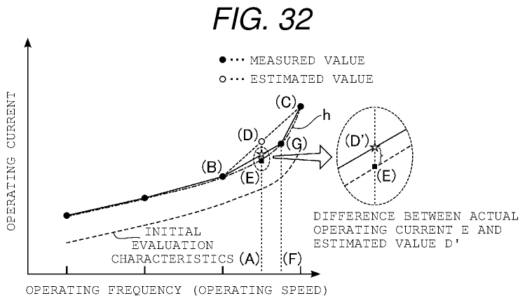

On the other hand, as illustrated in FIGS. 31 and 32, when the difference between the point (D) and the point (E) is large and the difference cannot be allowable as the information processing system, an operating current (G) at an operating frequency (F) is measured, and the operating current is obtained as follows. This will be described in a case where the electrical characteristics as illustrated by the broken line in FIG. 32 are illustrated in an initial evaluation stage. The electrical characteristics of the semiconductor chip do not necessarily match the broken line obtained in the initial evaluation but illustrate almost the same tendency, and the electrical characteristics are as illustrated by the one-dot chain line h. The operating current (G) at the operating frequency (F) is measured in the sorting test for the semiconductor chip. By interpolating the operating current at the operating frequency (A) from the measured values (B) and (G) to the straight line, a point (D′) can be obtained. A difference between an actual operating current indicated by the point (E) and the estimated point (D′) is smaller than the difference between the point (E) and the point (D), which becomes the range that is allowable as the information processing system. Therefore, the operating current at the point (D′) obtained by this approximation is used.

As described above, as a method for obtaining an operating current for a certain operating frequency, the correlation between the operating frequency and the operating currents is obtained by using the operating frequency and the measured value of the operating current at the time of the test. Then, the operating current for the certain operating frequency is approximated and estimated from the obtained correlation.

In addition, similarly, as a method for obtaining an operating current for a certain operating temperature, the correlation between the operating temperatures and the operating currents is obtained by using the operating temperature and the measured value of the operating current at the time of the test. Then, the operating current for the certain operating temperature is approximated and estimated from the obtained correlation.

### 8. Other Modification Examples and the Like

In the above-mentioned second and third embodiments, the supplied current is controlled on the basis of the operating temperature and the operating frequency, respectively, but the operating voltage and the operating currents thereof may be stored in the storage circuits SC instead of the operating temperature or the operating frequency, and the current supplied to the semiconductor chip or the semiconductor package may be controlled on the basis of the operating currents read from the storage circuit SC.

In the flowcharts described in the above embodiments, the order of processes can be changed as much as possible.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor circuit that consumes a first operating current when operating under a first operating condition and a second operating current when operating under a second operating condition, the second operating current being different from the first operating current; and
a storage circuit that stores a correspondence between the first and second operating currents and the first and second operating conditions, respectively.

2. The semiconductor device according to claim 1, wherein
each of the first and second operating conditions includes a first parameter, which is a type of an operation performed by the semiconductor circuit, and
the first operating condition includes a first type of operation as the first parameter, and the second operating condition includes a second type of operation as the first parameter, the second type being different from the first type.

3. The semiconductor device according to claim 2, wherein
the semiconductor circuit comprises a semiconductor memory, and
the first type of operation is one of a write operation, a read operation, and an erase operation with respect to the semiconductor memory device, and the second type of operation is another one of the write operation, the read operation, and the erase operation.

4. The semiconductor device according to claim 3, wherein
each of the first and second operating conditions includes a second parameter, which is a temperature of the semiconductor device during the operation performed by the semiconductor circuit, and
the first operating condition includes a first temperature as the second parameter, and the second operating condition includes a second temperature as the second parameter, the second temperature being different from the first temperature.

5. The semiconductor device according to claim 4, further comprising:
a temperature detection circuit, and
the first and second temperatures stored in the storage circuit are values detected by the temperature detection circuit.

6. The semiconductor device according to claim 4, wherein
each of the first and second operating conditions includes a third parameter, which is an operating frequency of the operation performed by the semiconductor circuit, and
the first operating condition includes a first operating frequency as the third parameter, and the second operating condition includes a second operating frequency as the third parameter, the second operating frequency being different from the first operating frequency.

7. The semiconductor device according to claim 6, wherein
each of the first and second operating conditions includes a fourth parameter, which is an operating voltage of the operation performed by the semiconductor circuit, and
the first operating condition includes a first operating voltage as the fourth parameter, and the second operating condition includes a second operating voltage as the fourth parameter, the second operating voltage being different from the first operating voltage.

8. The semiconductor device according to claim 1, wherein
each of the first and second operating conditions includes a second parameter, which is a temperature of the semiconductor device during an operation performed by the semiconductor circuit, and
the first operating condition includes a first temperature as the second parameter, and the second operating condition includes a second temperature as the second parameter, the second temperature being different from the first temperature.

9. The semiconductor device according to claim 1, wherein
each of the first and second operating conditions includes a third parameter, which is an operating frequency of an operation performed by the semiconductor circuit, and
the first operating condition includes a first operating frequency as the third parameter, and the second operating condition includes a second operating frequency as the third parameter, the second operating frequency being different from the first operating frequency.

10. The semiconductor device according to claim 1, wherein
each of the first and second operating conditions includes a fourth parameter, which is an operating voltage of an operation performed by the semiconductor circuit, and
the first operating condition includes a first operating voltage as the fourth parameter, and the second operating condition includes a second operating voltage as the fourth parameter, the second operating voltage being different from the first operating voltage.

11. The semiconductor device according to claim 1, wherein
the semiconductor circuit comprises a semiconductor memory, and
the storage circuit is included as a part of the semiconductor memory.

12. The semiconductor device according to claim 1, wherein
the semiconductor device comprises a semiconductor chip, and
the semiconductor circuit comprises a memory controller configured to control one or more semiconductor memory chips external to the semiconductor chip.

13. The semiconductor device according to claim 1, wherein
the first operating current is a value of a current consumed in the semiconductor circuit at a point in time during operation under the first operating condition, and
the second operating current is a value of a current consumed in the semiconductor circuit at a point in time during operation under the second operating condition.

14. The semiconductor device according to claim 1, wherein
the first operating current is an average value of a current consumed in the semiconductor circuit during operation under the first operating condition, and
the second operating current is an average value of a current consumed in the semiconductor circuit during operation under the second operating condition.

15. A semiconductor device comprising:
a first semiconductor chip including:
a first semiconductor circuit that consumes a first operating current when operating under a first operating condition and a second operating current when operating under a second operating condition, the second operating current being different from the first operating current; and
a first storage circuit that stores a correspondence between the first and second operating currents and the first and second operating conditions, respectively; and
a second semiconductor chip including:
a second semiconductor circuit that consumes a third operating current when operating under the first operating condition and a fourth operating current when operating under the second operating condition, the third operating current being different from the fourth operating current; and
a second storage circuit that stores a correspondence between the third and fourth operating currents and the first and second operating conditions, respectively.

16. The semiconductor device according to claim 15, wherein the first semiconductor chip has a same circuit structure as the second semiconductor chip.

17. The semiconductor device according to claim 15, wherein the first semiconductor chip has a different circuit structure from the second semiconductor chip.

18. The semiconductor device according to claim 15, wherein
each of the first and second operating conditions includes one or more of first, second, third, and fourth parameters,
the first parameter being a type of an operation performed by the corresponding semiconductor circuit,
the second parameter being a temperature of the corresponding semiconductor chip during the operation,
the third parameter being an operating frequency of the operation, and
the fourth parameter being an operating voltage of the operation.

19. A semiconductor device comprising:
a first semiconductor package including a first plurality of semiconductor chips, at least one of which includes:
a first semiconductor circuit that consumes a first operating current when operating under a first operating condition and a second operating current when operating under a second operating condition, the second operating current being different from the first operating current; and
a first storage circuit that stores a correspondence between the first and second operating currents and the first and second operating conditions, respectively; and
a second semiconductor package including a second plurality of semiconductor chips, at least one of which includes:
a second semiconductor circuit that consumes a third operating current when operating under the first operating condition and a fourth operating current when operating under the second operating condition, the third operating current being different from the fourth operating current; and
a second storage circuit that stores a correspondence between the third and fourth operating currents and the first and second operating conditions, respectively.

20. The semiconductor device according to claim 19, wherein
each of the first and second operating conditions includes one or more of first, second, third, and fourth parameters,
the first parameter being a type of an operation performed by the corresponding semiconductor circuit,
the second parameter being a temperature of the corresponding semiconductor chip during the operation,
the third parameter being an operating frequency of the operation, and
the fourth parameter being an operating voltage of the operation.
